(19) United States
(12) Patent Application Publication
(10) Pub. No.: US 2025/0127006 A1
(43) Pub. Date: Apr. 17, 2025

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Hong CHEN, Beijing (CN); Miao WANG, Beijing (CN); Ge WANG, Beijing (CN); Zhiliang JIANG, Beijing (CN); Chenxi LI, Beijing (CN); Dengyu WANG, Beijing (CN); Xiang LUO, Beijing (CN); Ge NIU, Beijing (CN); Hongli WANG, Beijing (CN)

(21) Appl. No.: 18/833,987

(22) PCT Filed: Nov. 8, 2023
(86) PCT No.: PCT/CN2023/130420

§ 371 Date: Jul. 29, 2024

(30) Foreign Application Priority Data
Dec. 16, 2022 (CN) 202211623107.2

(51) Int. Cl. H10K 59/35

(52) U.S. Cl. CPC H10K 59/353; H10K 59/351

(57) ABSTRACT

The present disclosure provides a display panel and a display apparatus, and belongs to the field of display technology. The display panel includes a plurality of pixel units each including a plurality of subpixels. At least one subpixel in at least one pixel unit is adjacent to at least two support parts, an angle is formed between connection lines respectively connecting centers of the at least two support parts adjacent to the at least one subpixel and a center of the subpixel, and two angles adjacent in a first direction have different orientations.

### TECHNICAL FIELD

The present disclosure relates to the field of display technology, and specifically relates to a display panel and a display apparatus.

### BACKGROUND

In the organic light-emitting diode (OLED) backplane process, a pixel support (PS) among pixels mainly plays a supporting role. For example, a PS is formed on a pixel defining layer (PDL) to support a fine metal mask (FMM), and a luminescent material is evaporated on an emission region defined by the PDL through the FMM to form pixels.

However, a non-uniform, insufficient, or poorly symmetrical PS as a whole will cause non-flatness of the FMM supported by the PS, resulting in color cast of the display panel to some extent.

### SUMMARY

To solve at least one of the technical problems in the existing art, the present disclosure provides a display panel and a display apparatus.

In a first aspect, a technical solution adopted to solve the technical problem of the present disclosure is a display panel, including a plurality of pixel units each including a plurality of subpixels; wherein at least one subpixel in at least one pixel unit is adjacent to at least two support parts, an angle is formed between connection lines respectively connecting centers of the at least two support parts adjacent to the at least one subpixel and a center of the subpixel, and two angles adjacent in a first direction have different orientations.

In some embodiments, the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups include first support part groups and second support part groups; and the first support part groups and the second support part groups in the same row are alternated in the row direction;
each first support part group includes a first support part and a second support part; wherein the first support part is disposed between two of the subpixels, and the second support part is disposed between two of the subpixels; and
each second support part group includes a third support part and a fourth support part; wherein the third support part is disposed between two of the subpixels, and the fourth support part is disposed between two of the subpixels.

In some embodiments, a first support part group and a second support part group in the same row adjacent to each other are axisymmetric with respect to a straight line passing, in a second direction, through a midpoint of a connection line segment connecting centers of the first support part and the third support part; and/or
two adjacent first support part groups in the same column are axisymmetric with respect to a straight line passing, in the first direction, through a midpoint of a connection line segment connecting centers of two first support parts; the first direction is perpendicular to the second direction; and two adjacent second support part groups in the same column are axisymmetric with respect to a straight line passing, in the first direction, through a midpoint of a connection line segment connecting centers of two third support parts.

In some embodiments, the plurality of support parts are divided into a plurality of support part groups arranged in an array, including first support part groups and second support part groups; and the first support part groups and the second support part groups in the same row are alternated in the row direction;
each first support part group includes a first support part and a second support part; wherein the first support part is disposed between two of the subpixels, and the second support part is disposed between two of the subpixels; and
each second support part group includes a third support part and a fourth support part; wherein the third support part is disposed between two of the subpixels, and the fourth support part is disposed between two of the subpixels.

In some embodiments, a first support part group and a second support part group in the same row adjacent to each other are axisymmetric with respect to a straight line passing, in a second direction, through a midpoint of a connection line segment connecting centers of the first support part and the third support part; and/or
two adjacent first support part groups in the same column are axisymmetric with respect to a straight line passing, in the first direction, through a midpoint of a connection line segment connecting centers of two first support parts; the first direction is perpendicular to the second direction; and two adjacent second support part groups in the same column are axisymmetric with respect to a straight line passing, in the first direction, through a midpoint of a connection line segment connecting centers of two third support parts.

In some embodiments, the plurality of support parts are divided into multiple rows of third support part groups, and the third support part groups in adjacent rows are staggered in a row direction; and the plurality of support parts are divided into multiple columns of third support part groups, and the third support part groups in adjacent columns are staggered in a column direction; and
each third support part group includes a first support part, a second support part, a third support part, and a fourth support part arranged around one subpixel of a pixel unit.

In some embodiments, the plurality of support parts are divided into a plurality of third support part groups arranged in an array; and each third support part group includes a first support part, a second support part, a third support part, and a fourth support part arranged around one subpixel of a pixel unit.

In some embodiments, two adjacent third support part groups in the same column are axisymmetric with respect to a straight line passing, in a row direction, through a midpoint of a connection line segment connecting centers of two first support parts; and
two adjacent third support part groups in the same row are axisymmetric with respect to a straight line passing, in a column direction, through a midpoint of a connection line segment connecting centers of two first support parts.

In some embodiments, the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups include first support part groups, second support part groups, and third support part groups; the third support part groups are positioned in even-numbered rows of the plurality of support part groups; and the first support part groups and the second support part groups are positioned in odd-numbered rows of the plurality of support part groups, and the first support part groups and the second support part groups in the same row are alternated in the row direction;
each first support part group includes a first support part and a second support part; wherein the first support part is disposed between two of the subpixels, and the second support part is disposed between two of the subpixels;
each second support part group includes a third support part and a fourth support part; wherein the third support part is disposed between two of the subpixels, and the fourth support part is disposed between two of the subpixels; and
each third support part group includes a fifth support part, a sixth support part, a seventh support part, and an eighth support part arranged around one subpixel of a pixel unit.

In some embodiments, the plurality of support part groups in the same column are all the first support part groups, or all the second support part groups, or all the third support part groups;
two adjacent first support part groups in the same column are axisymmetric with respect to a straight line passing, in a row direction, through a midpoint of a connection line segment connecting centers of two first support parts; two adjacent second support part groups in the same column are axisymmetric with respect to a straight line passing, in the row direction, through a midpoint of a connection line segment connecting centers of two third support parts; and two adjacent third support part groups in the same column are axisymmetric with respect to a straight line passing, in the row direction, through a midpoint of a connection line segment connecting centers of two fifth support parts; and
a first support part group and a second support part group in the same row adjacent to each other are axisymmetric with respect to a straight line passing, in the column direction, through a midpoint of a connection line segment connecting centers of the first support part and the third support part; and two adjacent third support part groups in the same row are axisymmetric with respect to a straight line passing, in the column direction, through a midpoint of a connection line segment connecting centers of the fifth support part and the eighth support part.

In some embodiments, the angle formed between connection lines respectively connecting centers of the at least two support parts adjacent to the at least one subpixel and a center of the subpixel is not equal to 90°.

In some embodiments, the plurality of subpixels include a first subpixel, a second subpixel, a third subpixel, and a fourth subpixel, the first subpixel, the second subpixel, and the third subpixel are different from each other, and the first subpixel is the same as the fourth subpixel;
among the plurality of pixel units, the first subpixel and the fourth subpixel are alternated in a row direction to form a plurality of first pixel rows, and the first subpixel and the fourth subpixel are alternated in a column direction to form a plurality of first pixel columns; and the second subpixel and the third subpixel are alternated in the row direction to form a plurality of second pixel rows, and the second subpixel and the third subpixel are alternated in a column direction to form a plurality of second pixel columns;
for one second subpixel, a support part is provided between the second subpixel and a third subpixel adjacent to and positioned in the same column as the second subpixel, and a support part is provided between the second subpixel and another third subpixel adjacent to and positioned in the same column as the second subpixel, or a support part is provided between the second subpixel and a third subpixel adjacent to and positioned in the same row as the second subpixel;
for at least two of the support parts, a connection line connecting a center of one support part and a center of a third subpixel adjacent to the one support part, and a connection line connecting the center of the one support part and a fourth subpixel adjacent to the one support part form an angle marked as a first angle; and a connection line connecting a center of the other support part and a center of a third subpixel adjacent to the other support part, and a connection line connecting the center of the other support part and a fourth subpixel adjacent to the other support part form an angle marked as a second angle; and
the first angle and the second angle have different orientations.

In some embodiments, the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups include first support part groups and second support part groups; and the first support part groups and the second support part groups in the same row are alternated in the row direction;
each first support part group includes a first support part and a second support part; wherein the first support part is disposed between the second subpixel and the third subpixel in a pixel unit, and the second support part is disposed between the fourth subpixel in the pixel unit and a first subpixel adjacent to and positioned in a different first pixel row from the fourth subpixel; and
each second support part group includes a third support part and a fourth support part; wherein the third support part is disposed between the second subpixel and the third subpixel in the pixel unit, and the fourth support part is disposed between the first subpixel in the pixel unit and a fourth subpixel adjacent to and positioned in a different first pixel row from the first subpixel.

In some embodiments, the plurality of support parts are divided into a plurality of support part groups arranged in an array, including first support part groups and second support part groups; and the first support part groups and the second support part groups in the same row are alternated in the row direction;
each first support part group includes a first support part and a second support part; wherein the first support part is disposed between the second subpixel and the third subpixel in the pixel unit, and the second support part is disposed between the fourth subpixel in the pixel unit and a first subpixel adjacent to and positioned in a different first pixel row from the fourth subpixel; and
each second support part group includes a third support part and a fourth support part; wherein the third support part is disposed between the second subpixel and the third subpixel in the pixel unit, and the fourth support part is disposed between the first subpixel in the pixel unit and a fourth subpixel adjacent to and positioned in a different first pixel row from the first subpixel.

In some embodiments, the plurality of support part groups in the same column are all the first support part groups, or all the second support part groups; two adjacent first support part groups in the same column are axisymmetric with respect to a straight line passing, in a row direction, through a midpoint of a connection line segment connecting centers of two first support parts; and two adjacent second support part groups in the same column are axisymmetric with respect to a straight line passing, in the row direction, through a midpoint of a connection line segment connecting centers of two third support parts; and
a first support part group and a second support part group in the same row adjacent to each other are axisymmetric with respect to a straight line passing, in the column direction, through a midpoint of a connection line segment connecting centers of the first support part and the third support part.

In some embodiments, the plurality of support parts are divided into multiple rows of third support part groups, and the third support part groups in adjacent rows are staggered in a row direction; and the plurality of support parts are divided into multiple columns of third support part groups, and the third support part groups in adjacent columns are staggered in a column direction; and
each third support part group includes a first support part, a second support part, a third support part, and a fourth support part; wherein the first support part is disposed between the second subpixel and the third subpixel in a pixel unit, and the second support part, the third support part, and the fourth support part are respectively disposed between the fourth subpixel in the pixel unit and three first subpixels adjacent to the fourth subpixel.

In some embodiments, the plurality of support parts are divided into a plurality of third support part groups arranged in an array; and each third support part group includes a first support part, a second support part, a third support part, and a fourth support part; wherein the first support part is disposed between the second subpixel and the third subpixel in the pixel unit, and the second support part, the third support part, and the fourth support part are respectively disposed between the fourth subpixel in the pixel unit and three first subpixels adjacent to the fourth subpixel.

In some embodiments, two adjacent third support part groups in the same column are axisymmetric with respect to a straight line passing, in a row direction, through a midpoint of a connection line segment connecting centers of two first support parts; and
two adjacent third support part groups in the same row are axisymmetric with respect to a straight line passing, in a column direction, through a midpoint of a connection line segment connecting centers of fourth subpixels adjacent to two first support parts.

In some embodiments, for two adjacent third support part groups in the same row, one fourth subpixel is between the fourth support part in one of the third support part groups and the first support part in the other third support part group, to space apart the fourth and first support parts; and
for two adjacent third support part groups in the same column, one fourth subpixel is between the third support part in one of the third support part groups and the second support part in the other third support part group, to space apart the third and second support parts.

In some embodiments, for two adjacent third support part groups in the same row, at least three fourth subpixels are between the fourth support part in one of the third support part groups and the first support part in the other third support part group, to space apart the fourth and first support parts; and
for two adjacent third support part groups in the same column, at least three fourth subpixels are between the third support part in one of the third support part groups and the second support part in the other third support part group, to space apart the third and second support parts.

In some embodiments, each support part has an orthographic projection with a rectangular contour shape.

In some embodiments, the display panel further includes a base substrate, and a pixel defining layer on the base substrate, the pixel defining layer having openings in one-to-one correspondence with the subpixels;
the first subpixel and the fourth subpixel are both green subpixels, the second subpixel is a blue subpixel, and the third subpixel is a red subpixel; and an opening corresponding to the blue subpixel has an orthographic projection on the base substrate with a polygonal contour shape; and
a corner angle of the opening corresponding to the blue subpixel includes a first corner and a second corner disposed oppositely, and a third corner and a fourth corner disposed oppositely, the second corner, the third corner, and the fourth corner have the same contour shape, and a distance from an intersection point of extension lines of two sides of the first corner to a center of the opening is greater than a distance from an intersection point of extension lines of two sides of the second corner to the center of the opening.

In some embodiments, the plurality of support parts are divided into multiple rows of third support part groups, and the third support part groups in adjacent rows are staggered in a row direction; and the plurality of support parts are divided into multiple columns of third support part groups, and the third support part groups in adjacent columns are staggered in a column direction; and
each third support part group includes a first support part, a second support part, a third support part, and a fourth support part; wherein the first support part is disposed between the second subpixel and the third subpixel in the pixel unit, and the second support part, the third support part, and the fourth support part are respectively disposed between the fourth subpixel in the pixel unit and three first subpixels adjacent to the fourth subpixel.

In some embodiments, the plurality of support parts are divided into a plurality of third support part groups arranged in an array; and each third support part group includes a first support part, a second support part, a third support part, and a fourth support part; wherein the first support part is disposed between the second subpixel and the third subpixel in the pixel unit, and the second support part, the third support part, and the fourth support part are respectively disposed between the fourth subpixel in the pixel unit and three first subpixels adjacent to the fourth subpixel.

In some embodiments, an orthographic projection of each support part on the base substrate has a contour shape including a polygonal shape; and
a corner angle of the support part includes a fifth corner and a sixth corner disposed oppositely, and a seventh corner and an eighth corner disposed oppositely, wherein the sixth corner, the seventh corner, and the eighth corner have the same contour shape, and a distance from an intersection point of extension lines of two sides of the fifth corner of the support part to a center of the support part is greater than a distance from an intersection point of extension lines of two sides of the sixth corner to the center of the support part.

In some embodiments, for each support part in each third support part group, the fifth corner is farther away from a fourth subpixel adjacent to the support part than the sixth corner.

In some embodiments, for each support part in each third support part group, the fifth corner is closer to a fourth subpixel adjacent to the support part than the sixth corner.

In some embodiments, for two adjacent rows of third support part groups, the fifth corner of each support part in one row of third support part groups is closer to a fourth subpixel adjacent to the support part than the sixth corner, while the fifth corner of each support part in the other row of third support part groups is farther away from a fourth subpixel adjacent to the support part than the sixth corner.

In some embodiments, the first corner includes a rounded or flat chamfer.

In some embodiments, the fifth corner includes a rounded or flat chamfer.

In some embodiments, the first corner and the fifth corner have the same contour shape.

In some embodiments, the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups include first support part groups and second support part groups; and the first support part groups and the second support part groups in the same row are alternated in the row direction;
each first support part group includes a first support part and a second support part; wherein the first support part is disposed between the second subpixel and the third subpixel in the pixel unit, and the second support part is disposed between the fourth subpixel in the pixel unit and a first subpixel adjacent to and positioned in the same first pixel row as the fourth subpixel; and
each second support part group includes a third support part and a fourth support part; wherein the third support part and the fourth support part are respectively disposed between the fourth subpixel in the pixel unit and two first subpixels adjacent to and positioned in different first pixel rows from the fourth subpixel.

In some embodiments, an orthographic projection of each support part on the base substrate has a contour shape including a polygonal shape; and a corner angle of the support part includes a fifth corner and a sixth corner disposed oppositely, and a seventh corner and an eighth corner disposed oppositely, wherein the sixth corner, the seventh corner, and the eighth corner have the same contour shape, and a distance from an intersection point of extension lines of two sides of the fifth corner of the support part to a center of the support part is greater than a distance from an intersection point of extension lines of two sides of the sixth corner to the center of the support part; and
for two adjacent rows of support part groups, the fifth corner of each support part in one row of support part groups is closer to a fourth subpixel adjacent to the support part than the sixth corner, while the fifth corner of each support part in the other row of support part groups is farther away from a fourth subpixel adjacent to the support part than the sixth corner.

In some embodiments, the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups include first support part groups, second support part groups, and third support part groups; the third support part groups are positioned in even-numbered rows of the plurality of support part groups; and the first support part groups and the second support part groups are positioned in odd-numbered rows of the plurality of support part groups, and the first support part groups and the second support part groups in the same row are alternated in the row direction;
each first support part group includes a first support part and a second support part; wherein the first support part is disposed between the second subpixel and the third subpixel in the pixel unit, and the second support part is disposed between the fourth subpixel in the pixel unit and a first subpixel adjacent to and positioned in a different first pixel row from the fourth subpixel;
each second support part group includes a third support part and a fourth support part; wherein the third support part is disposed between the fourth subpixel in the pixel unit and a first subpixel adjacent to and positioned in the same first pixel row as the fourth subpixel; the fourth support part is disposed between the fourth subpixel in the pixel unit and a first subpixel adjacent to and positioned in a different first pixel row as the fourth subpixel; and
each third support part group includes a fifth support part, a sixth support part, a seventh support part, and an eighth support part; wherein the fifth support part is disposed between the second subpixel and the third subpixel in the pixel unit, and the sixth support part, the seventh support part, and the eighth support part are respectively disposed between the fourth subpixel in the pixel unit and three first subpixels adjacent to the fourth subpixel.

In some embodiments, an orthographic projection of each support part on the base substrate has a contour shape including a polygonal shape; and a corner angle of the support part includes a fifth corner and a sixth corner disposed oppositely, and a seventh corner and an eighth corner disposed oppositely, wherein the sixth corner, the seventh corner, and the eighth corner have the same contour shape, and a distance from an intersection point of extension lines of two sides of the fifth corner of the support part to a center of the support part is greater than a distance from an intersection point of extension lines of two sides of the sixth corner to the center of the support part;
for the first support part groups and the second support part groups, the fifth corner of each support part is closer to a fourth subpixel adjacent to the support part than the sixth corner; and
for the third support part groups, the fifth corner of each support part is farther away from a fourth subpixel adjacent to the support part than the sixth corner.

In some embodiments, the plurality of support part groups in the same column are all the first support part groups, or all the second support part groups, or all the third support part groups;
two adjacent first support part groups in the same column are axisymmetric with respect to a straight line passing, in a row direction, through a midpoint of a connection line segment connecting centers of two first support parts; two adjacent second support part groups in the same column are axisymmetric with respect to a straight line passing, in the row direction, through a midpoint of a connection line segment connecting centers of two third support parts; and two adjacent third support part groups in the same column are axisymmetric with respect to a straight line passing, in the row direction, through a midpoint of a connection line segment connecting centers of two fifth support parts; and
a first support part group and a second support part group in the same row adjacent to each other are axisymmetric with respect to a straight line passing, in the column direction, through a midpoint of a connection line segment connecting centers of the first support part and the third support part; and two adjacent third support part groups in the same row are axisymmetric with respect to a straight line passing, in the column direction, through a midpoint of a connection line segment connecting centers of the fifth support part and the eighth support part.

In some embodiments, the plurality of support parts are divided into a plurality of support part groups arranged in an array, including first support part groups and second support part groups; and the first support part groups and the second support part groups are alternated in both the row direction and the column direction;
each first support part group includes a first support part and a second support part; wherein the first support part is disposed between the second subpixel and the third subpixel in the pixel unit, and the second support part is disposed between the second subpixel in the pixel unit and a third subpixel adjacent to and positioned in a different second pixel row from the second subpixel; and
each second support part group includes a third support part and a fourth support part; wherein the third support part and the fourth support part are respectively disposed between the second subpixel in the pixel unit and two third subpixels adjacent to and positioned in the same row as the second subpixel.

In some embodiments, the second subpixel is a red subpixel.

In some embodiments, the first support part, the second support part, the third support part, and the fourth support part each have an orthographic projection with a circular contour shape.

In some embodiments, for a first support part group and a second support part group in the same row adjacent to each other, one third subpixel is between a second subpixel disposed between the first support part and the second support part in the first support part group, and a second subpixel disposed between the third support part and the fourth support part in the second support part group, to space apart the two second subpixels; and
for a first support part group and a second support part group in the same column adjacent to each other, one third subpixel is between a second subpixel between the first support part and the second support part in the first support part group, and a second subpixel disposed between the third support part and the fourth support part in the second support part group, to space apart the two second subpixels.

In some embodiments, each support part has an orthographic projection with a contour shape including at least one of: a rectangular shape, a circular shape, an oval shape, a triangular shape, a drop shape, an asymmetric oval shape, or a trapezoidal shape.

In a second aspect, an embodiment of the present disclosure further provides a display apparatus, including the display panel as described in any of the above embodiments.

### BRIEF DESCRIPTION OF DRAWINGS

FIG. 1 is a schematic diagram of a pixel array according to an embodiment of the present disclosure;

FIGS. 2a and 2b are schematic structural diagrams respectively showing support parts at different positions in a case where the second subpixel is a blue subpixel and the third subpixel is a red subpixel according to an embodiment of the present disclosure;

FIG. 3 is a schematic structural diagram showing some support parts in a case where the third subpixel is a blue subpixel and the second subpixel is a red subpixel according to an embodiment of the present disclosure;

FIG. 4 is a schematic diagram showing support parts arranged in pairs and support part groups formed of the support parts arranged in a staggered manner according to an embodiment of the present disclosure;

FIG. 5 is a schematic diagram showing support parts arranged in pairs and support part groups formed of the support parts arranged in an array according to an embodiment of the present disclosure;

FIG. 6 is a schematic diagram showing support parts arranged in symmetrical crosses and support part groups formed of the support parts arranged in a staggered manner according to an embodiment of the present disclosure;

FIG. 7 is a schematic diagram showing support parts arranged in symmetrical crosses and support part groups formed of the support parts arranged in an array according to an embodiment of the present disclosure;

FIG. 8 is a schematic diagram showing support parts arranged in symmetrical crosses and support part groups formed of the support parts arranged in a staggered manner according to an embodiment of the present disclosure;

FIGS. 9a and 9b are schematic diagrams showing different contour shapes of subpixels according to an embodiment of the present disclosure;

FIG. 10 is a schematic diagram showing support parts arranged in symmetrical crosses and support part groups formed of the support parts arranged in a staggered manner according to an embodiment of the present disclosure;

FIG. 11 is a schematic diagram showing support parts arranged in symmetrical crosses and support part groups formed of the support parts arranged in an array according to an embodiment of the present disclosure;

FIG. 12 is a schematic diagram of support parts in the embodiment of FIG. 11 with fifth corners facing inward;

FIG. 13 is a schematic diagram of support parts in third support part groups of adjacent rows in the embodiment of FIG. 11 with fifth corners having different orientations;

FIG. 14 is a schematic diagram showing support parts arranged in pairs and support part groups formed of the support parts arranged in a staggered manner according to an embodiment of the present disclosure;

FIG. 15 is a schematic diagram showing support parts arranged partially in pairs and partially in symmetrical crosses, and support part groups formed of the support parts arranged in a staggered manner according to an embodiment of the present disclosure;

FIG. 16 is a schematic diagram showing support parts arranged in pairs and support part groups formed of the support parts arranged in an array according to an embodiment of the present disclosure;

FIG. 17 is a schematic diagram showing different shapes of exemplary first support parts and second support parts according to an embodiment of the present disclosure;

FIG. 18 is a schematic diagram showing different shapes of exemplary first support parts and second support parts according to another embodiment of the present disclosure; and

FIG. 19 is a schematic diagram showing layer structures of an exemplary display panel according to an embodiment of the present disclosure.

Reference Signs: 100. pixel unit; 1. first pixel row; 2. second pixel row; 3. first pixel column; 4. second pixel column; 01. first subpixel (green subpixel); 02. blue subpixel; 03. red subpixel; 04. fourth subpixel (green subpixel); 51. first support part group; 52. second support part group; 53. third support part group; 511. first support part; 512. second support part; 513. third support part; 514. fourth support part; 515. fifth support part; 516. sixth support part; 517. seventh support part; 518. eighth support part; 61. first corner; 62. second corner; 63. third corner; and 64. fourth corner.

### DETAIL DESCRIPTION OF EMBODIMENTS

To clarify the objects, technical solutions and advantages of the embodiments of the present disclosure, the technical solutions in the embodiments of the present disclosure will be clearly and completely described below with reference to the accompanying drawings in the embodiments of the present disclosure. Obviously, the described embodiments are merely some, not all, of the embodiments of the present disclosure. The components in the embodiments of the present disclosure, as generally described and illustrated in the figures herein, could be arranged and designed in a wide variety of different configurations. Therefore, the following detailed description of the embodiments of the present disclosure, provided in the accompanying drawings, is not intended to limit the claimed scope of the present disclosure, but is merely representative of selected embodiments of the present disclosure. All other embodiments, which can be derived by those skilled in the art from the embodiments of the present disclosure without making any creative effort, shall fall within the protection scope of the present disclosure.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, or the like are merely used to indicate a relative positional relationship, and when an absolute position of the described object is changed, the relative positional relationship may be changed accordingly.

Reference to “a plurality of or several” in the present disclosure means two or more. The term “and/or” describes an association relationship of associated objects, which may include three relationships; for example, A and/or B may refer to: A alone, A and B, or B alone. The character “/” generally indicates that the former and latter associated objects are in an “or” relationship.

It should be noted that, in the embodiments of the present disclosure, references to the row direction and the column direction only represent two different directions which are not limited to be perpendicular to each other. In the drawings of the embodiments of the present disclosure, the case where the row direction and the column direction are perpendicular to each other is merely used as an example for illustration, but does not constitute any limitation to the embodiments of the present disclosure.

In addition, references to identical, equal, and the like in the embodiments of the present disclosure do not mean that two objects are exactly the same in size and shape, but are allowed to be approximately the same, approximately equal or the like within a certain error range.

Before describing the display panel, the display apparatus and the high-resolution mask in the embodiments of the present disclosure, the specific structure of the display panel is firstly explained, where the display panel mainly includes a base substrate, and a pixel defining layer on the base substrate, the pixel defining layer having openings in one-to-one correspondence with subpixels. A shape of each subpixel is typically determined by a corresponding opening in the pixel defining layer, and an emission layer is at least partially formed in the opening, thereby defining a shape of an emission region of the subpixel, i.e., the contour shape of the orthographic projection of the subpixel mentioned in the embodiments of the present disclosure. Where the pixel opening has a polygonal shape, the subpixel also has a polygonal shape.

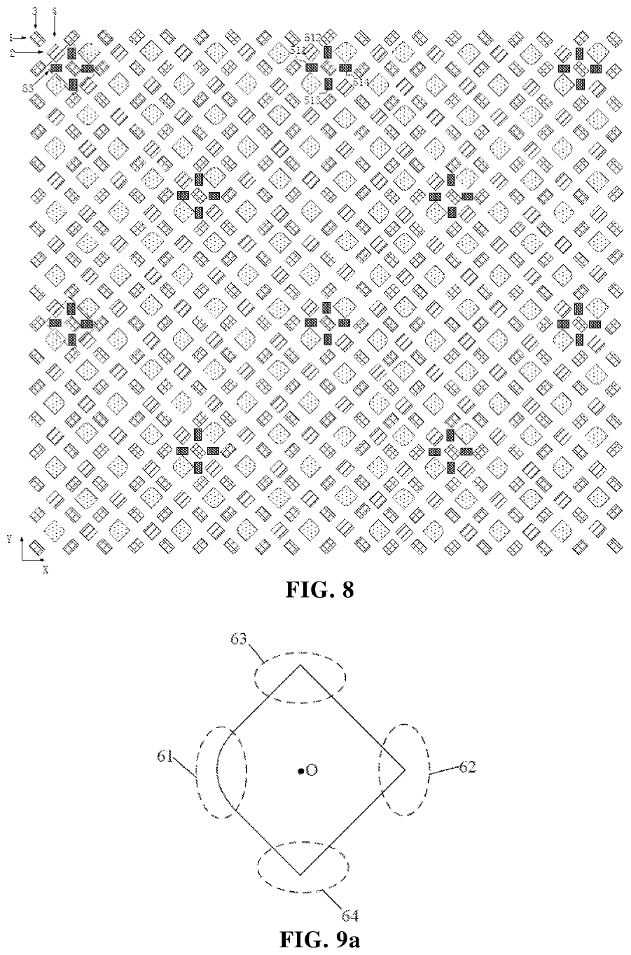

In addition, in the embodiments of the present disclosure, the first subpixel and the fourth subpixel are both green subpixels, one of the second subpixel and the third subpixel is a blue subpixel, while the other is a red subpixel. At least one of the red subpixel, the green subpixel, or the blue subpixel has a polygonal shape, and in the embodiments of the present disclosure, the case where the red, green and blue subpixels each have a polygonal shape is taken as an example for illustration. The polygonal shape may have three or more corners depending on its shape. For example, a quadrilateral or a quadrilateral-like shape includes four corner angles. FIGS. 9a and 9b are schematic diagrams showing contour shapes of subpixels according to an embodiment of the present disclosure. As shown in FIGS. 9a and 9b, each polygonal shape includes four corner angles, namely a first corner, a second corner, a third corner, and a fourth corner. The first corner and the second corner are disposed oppositely, and the third corner and the fourth corner are disposed oppositely. Apparently, it is to be understood that if the subpixel has a polygonal shape, there may be more corner angles, which is not limited in the embodiments of the present disclosure. In the embodiments of the present disclosure, the corner angle is not necessarily an angle between two lines, and in fact, it may be a rounded or flat chamfer. That is, two edges of a corner angle extend to a vertex of the corner angle, and a portion where the two edges of the corner angle meet at the vertex is formed into an arc line segment or a straight line segment. As shown in FIGS. 9a and 9b, in the embodiments of the present disclosure, the case where the first corner of at least one of the blue, red or green subpixel is a rounded or flat chamfer, and the remaining corners are close to right angles is taken as an example for illustration, but this does not form any limitation to the embodiments of the present disclosure. The second corner, the third corner and the fourth corner are substantially the same, for example, each close to a right angle, i.e., each may be a fillet, but have a curvature radius smaller than the first corner. It should be noted that the second corner, the third corner and the fourth corner substantially the same means that, for example, the three corners have the same angle, the same contour, the same size, the same fillet curvature and the like.

In the existing art, the PS includes a plurality of support parts each generally designed into a square or rectangular shape and typically disposed between a blue subpixel B and a red subpixel R in one pixel unit. One support part is provided for a plurality of pixel units, leading to unstable supporting performance due to the insufficient support parts. In addition, the support parts are arranged in pairs, for example, rectangular support parts in one pair are arranged horizontally and vertically, respectively, forming a PS with poor symmetry as a whole, which may cause non-flatness of the FMM supported by the PS, resulting in color cast of the display panel to some extent.

On this basis, an embodiment of the present disclosure provides a display panel, including a plurality of pixel units 100 each including a plurality of subpixels. At least one subpixel in at least one pixel unit 100 is adjacent to at least two support parts, an angle is formed between connection lines respectively connecting centers of the at least two support parts adjacent to the at least one subpixel and a center of the subpixel, and two angles adjacent in a first direction have different orientations, so as to reduce color cast caused by shielding of light in different directions.

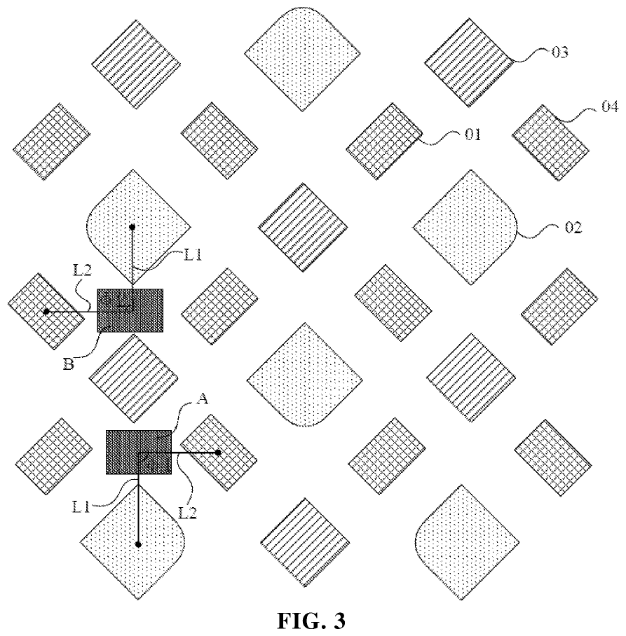

In some embodiments, as shown in FIG. 4, the plurality of support parts are divided into multiple rows of support part groups, and the support part groups in adjacent rows are staggered in a row direction; the plurality of support parts are divided into multiple columns of support part groups, and the support part groups in adjacent columns are staggered in a column direction. The support part groups include first support part groups 51 and second support part groups 52; and the first support part groups 51 and the second support part groups 52 in the same row are alternated in the row direction.

Each first support part group 51 includes a first support part 511 and a second support part 512; the first support part 511 is disposed between two of the subpixels in the pixel unit 100, and the second support part 512 is disposed between two of the subpixels; and the first support part 511 is different from the second support part 512. Each second support part group 52 includes a third support part 513 and a fourth support part 514; the third support part 513 is disposed between two of the subpixel, and the fourth support part 514 is disposed between two of the subpixels; and the third support part 513 is different from the fourth support part 514.

In some embodiments, with continued reference to FIG. 4, a first support part group 51 and a second support part group 52 in the same row adjacent to each other are axisymmetric with respect to a straight line passing, in a second direction Y, through a midpoint of a connection line segment connecting centers of the first support part 511 and the third support part 513; and/or
two adjacent first support part groups 51 in the same column are axisymmetric with respect to a straight line passing, in the first direction X, through a midpoint of a connection line segment connecting centers of two first support parts 511; the first direction X is perpendicular to the second direction Y; and two adjacent second support part groups 52 in the same column are axisymmetric with respect to a straight line passing, in the first direction X, through a midpoint of a connection line segment connecting centers of two third support parts 513.

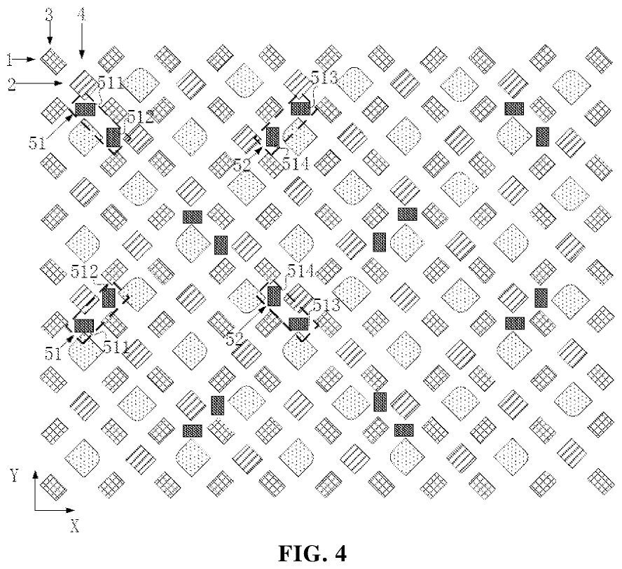

In some embodiments, as shown in FIG. 5, the plurality of support parts are divided into a plurality of support part groups arranged in an array, including first support part groups 51 and second support part groups 52. The first support part groups 51 and the second support part groups 52 in the same row are alternated in the row direction. Each first support part group 51 includes a first support part 511 and a second support part 512; the first support part 511 is disposed between two of the subpixels, the second support part 512 is disposed between two of the subpixels; and the first support part 511 is different from the second support part 512. Each second support part group 52 includes a third support part 513 and a fourth support part 514; the third support part 513 is disposed between two of the subpixel, and the fourth support part 514 is disposed between two of the subpixels; and the third support part 513 is different from the fourth support part 514.

In some embodiments, with continued reference to FIG. 5, a first support part group 51 and a second support part group 52 in the same row adjacent to each other are axisymmetric with respect to a straight line passing, in a second direction Y, through a midpoint of a connection line segment connecting centers of the first support part 511 and the third support part 513; and/or
two adjacent first support part groups 51 in the same column are axisymmetric with respect to a straight line passing, in the first direction X, through a midpoint of a connection line segment connecting centers of two first support parts 511; the first direction X is perpendicular to the second direction Y; and two adjacent second support part groups 52 in the same column are axisymmetric with respect to a straight line passing, in the first direction X, through a midpoint of a connection line segment connecting centers of two third support parts 513.

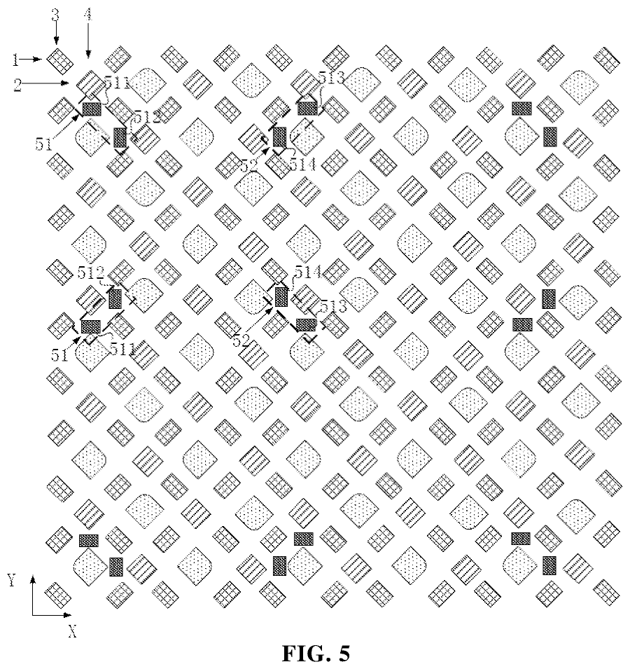

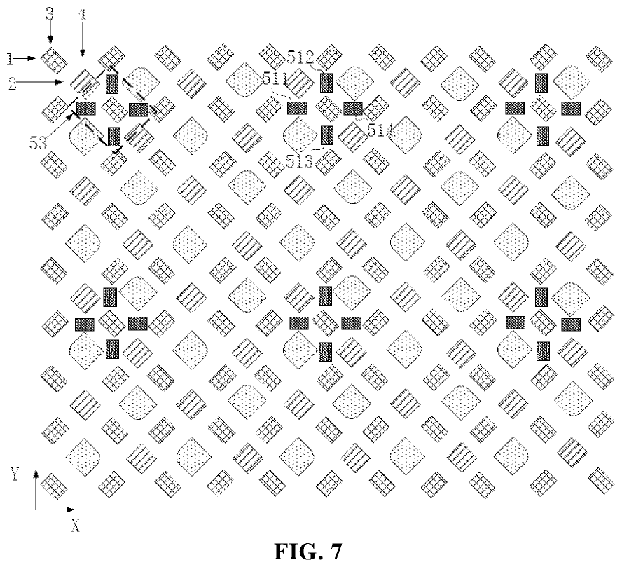

In some embodiments, as shown in FIG. 6 or 8, the plurality of support parts are divided into multiple rows of third support part groups 53, and the third support part groups 53 in adjacent rows are staggered in a row direction. The plurality of support parts are divided into multiple columns of third support part groups 53, and the third support part groups 53 in adjacent columns are staggered in a column direction. Each third support part group 53 includes a first support part 511, a second support part 512, a third support part 514, and a fourth support part 513 arranged around one subpixel of a pixel unit 100. For example, the first support part 511, the second support part 512, the third support part 513, and the fourth support part 514 are disposed around a green subpixel 04 of the pixel unit 100.

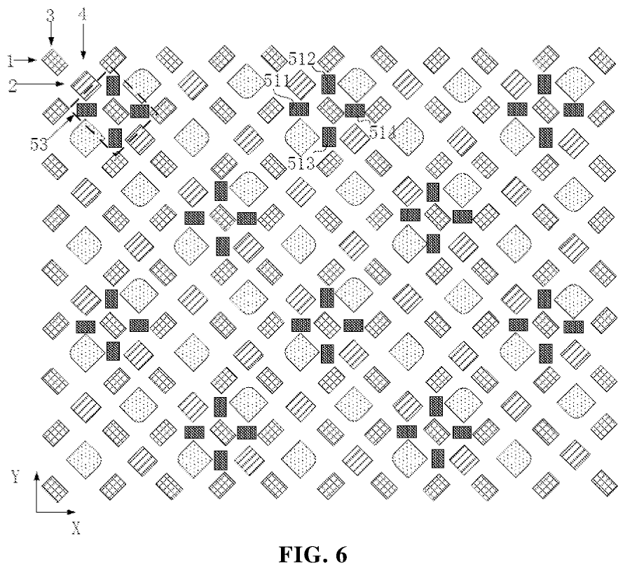

In some embodiments, as shown in FIG. 7, the plurality of support parts are divided into a plurality of third support part groups 53 arranged in an array. Each third support part group 53 includes a first support part 511, a second support part 512, a third support part 514, and a fourth support part 513 arranged around one subpixel of a pixel unit 100.

In some embodiments, as further shown in FIG. 7, two adjacent third support part groups 53 in the same column are axisymmetric with respect to a straight line passing, in a row direction, through a midpoint of a connection line segment connecting centers of two first support parts 511; and two adjacent third support part groups 53 in the same row are axisymmetric with respect to a straight line passing, in a column direction, through a midpoint of a connection line segment connecting centers of two first support parts 511.

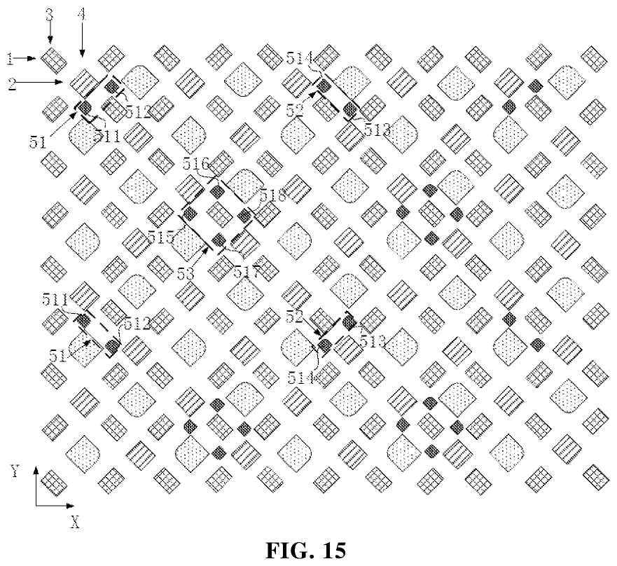

In some embodiments, as shown in FIG. 15, the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction. The support part groups include first support part groups 51, second support part groups 52, and third support part groups 53. The third support part groups 53 are positioned in even-numbered rows of the plurality of support part groups. The first support part groups 51 and the second support part groups 52 are positioned in odd-numbered rows of the plurality of support part groups, and the first support part groups 51 and the second support part groups 52 in the same row are alternated in the row direction. Each first support part group 51 includes a first support part 511 and a second support part 512. The first support part 511 is disposed between two of the subpixels, and the second support part 512 is disposed between two of the subpixels. Each second support part group 52 includes a third support part 513 and a fourth support part 514. The third support part 513 is disposed between two of the subpixel, and the fourth support part 514 is disposed between two of the subpixels. Each third support part group 53 includes a fifth support part 515, a sixth support part 516, a seventh support part 517, and an eighth support part 518 arranged around one subpixel of a pixel unit 100.

In some embodiments, as further shown in FIG. 15, the plurality of support part groups in the same column are all the first support part groups 51, or all the second support part groups 52, or all the third support part groups 53. Two adjacent first support part groups 51 in the same column are axisymmetric with respect to a straight line passing, in a row direction, through a midpoint of a connection line segment connecting centers of two first support parts 511. Two adjacent second support part groups 52 in the same column are axisymmetric with respect to a straight line passing, in the row direction, through a midpoint of a connection line segment connecting centers of two third support parts 513. Two adjacent third support part groups 53 in the same column are axisymmetric with respect to a straight line passing, in the row direction, through a midpoint of a connection line segment connecting centers of two fifth support parts 515. A first support part group 51 and a second support part group 52 in the same row adjacent to each other are axisymmetric with respect to a straight line passing, in the column direction, through a midpoint of a connection line segment connecting centers of the first support part 511 and the third support part 513. Two adjacent third support part groups 53 in the same row are axisymmetric with respect to a straight line passing, in the column direction, through a midpoint of a connection line segment connecting centers of the fifth support part 515 and the eighth support part 518.

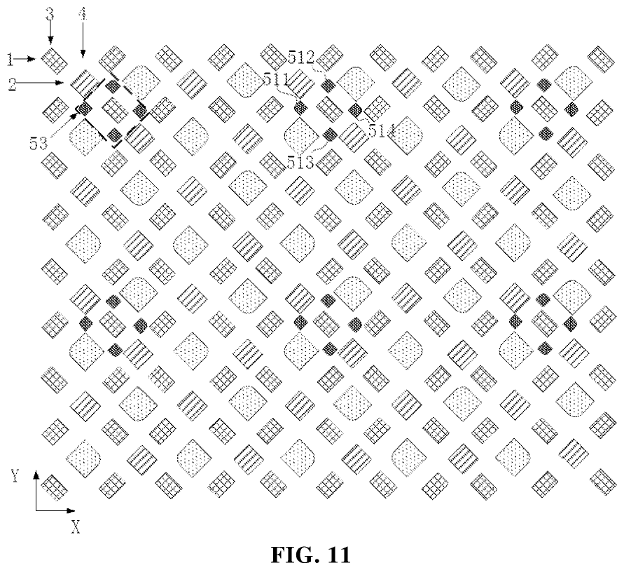

In some embodiments, as shown in FIG. 11, the angle formed between connection lines respectively connecting centers of the at least two support parts adjacent to the at least one subpixel and a center of the subpixel is not equal to 90°. Here, since a larger chamfer of the support part is matched with a blue subpixel 02 to cause centers thereof offset, by providing the angle formed between connection lines respectively connecting centers of the at least two support parts adjacent to the at least one subpixel and a center of the subpixel not equal to 90°, the color cast caused by shielding of light in different directions can be reduced.

In some embodiments, the display panel includes a plurality of pixel units each including a plurality of subpixels, including a first subpixel, a second subpixel, a third subpixel, and a fourth subpixel. The first subpixel, the second subpixel, and the third subpixel are different from each other, and the first subpixel is the same as the fourth subpixel. In the embodiments of the present disclosure, the display panel refers to an arrangement structure of different colors of light-emitting devices in a display substrate, which is not limited to an arrangement structure of pixel circuits for driving the respective light-emitting devices. Accordingly, it is to be understood that the subpixels in the embodiments of the present disclosure refer to a light-emitting device structure, and the first subpixel (or the fourth subpixel), the second subpixel, and the third subpixel represent three different colors of subpixels. In the embodiments of the present disclosure, the case where the first subpixel is a green subpixel 01, the fourth subpixel is a green subpixel 04, one of the second subpixel and the third subpixel is a blue subpixel 02, and the other is a red subpixel 03 is taken as an example for illustration. However, the case does not form any limitation to the protection scope of the embodiments of the present disclosure.

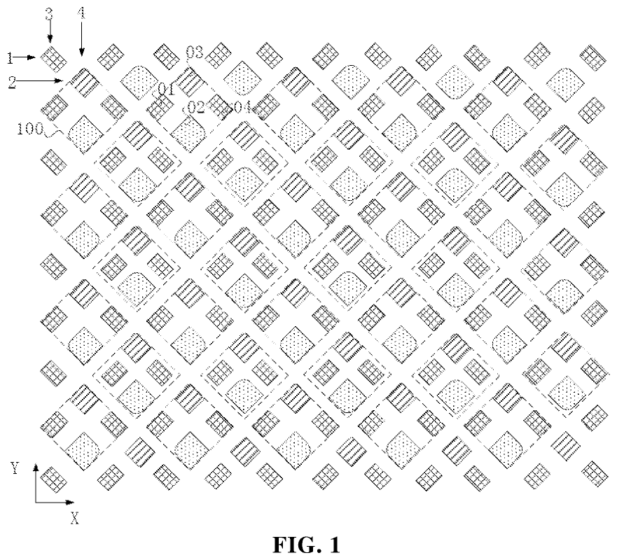

FIG. 1 is a schematic diagram of a pixel array according to an embodiment of the present disclosure. As shown in FIG. 1, among the plurality of pixel units 100, the first subpixel and the fourth subpixel are alternated in a row direction to form a plurality of first pixel rows 1, and the first subpixel and the fourth subpixel are alternated in a column direction to form a plurality of first pixel columns 3; and the second subpixel and the third subpixel are alternated in the row direction to form a plurality of second pixel rows 2, and the second subpixel and the third subpixel are alternated in a column direction to form a plurality of second pixel columns 4. As shown in FIG. 1, the row direction may be a first direction X, and the column direction may be a second direction Y.

For one second subpixel, a support part is provided between the second subpixel and a third subpixel adjacent to and positioned in the same column as the second subpixel, and a support part is provided between the second subpixel and another third subpixel adjacent to and positioned in the same column as the second subpixel, or a support part is provided between the second subpixel and a third subpixel adjacent to and positioned in the same row as the second subpixel.

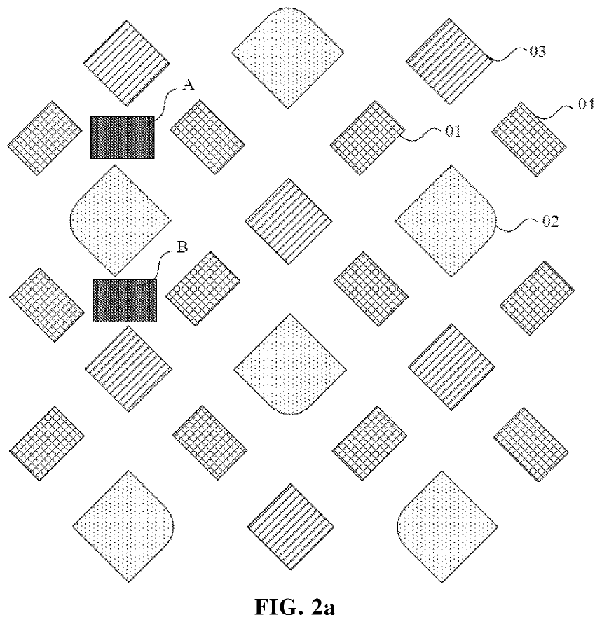

FIGS. 2a and 2b are schematic structural diagrams respectively showing support parts at different positions in a case where the second subpixel is a blue subpixel and the third subpixel is a red subpixel according to an embodiment of the present disclosure. As shown in FIG. 2a, a support part A is disposed between a blue subpixel 02 and a red subpixel 03 adjacent to and disposed in the same column as the blue subpixel 02; and a support part B is disposed between the blue subpixel 02 and another red subpixel 03 adjacent to and disposed in the same column as the blue subpixel 02. As shown in FIG. 2b, a support part A is disposed between a blue subpixel 02 and a red subpixel 03 adjacent to and disposed in the same column as the blue subpixel 02, and a support part B is disposed between the blue subpixel 02 and another red subpixel 03 adjacent to and disposed in the same row as the blue subpixel 02; and a support part C is disposed between another blue subpixel 02 and a red subpixel 03 adjacent to and disposed in the same column as the another blue subpixel 02, and a support part D is disposed between the another blue subpixel 02 and a red subpixel 03 adjacent to and disposed in the same row as the another blue subpixel 02.

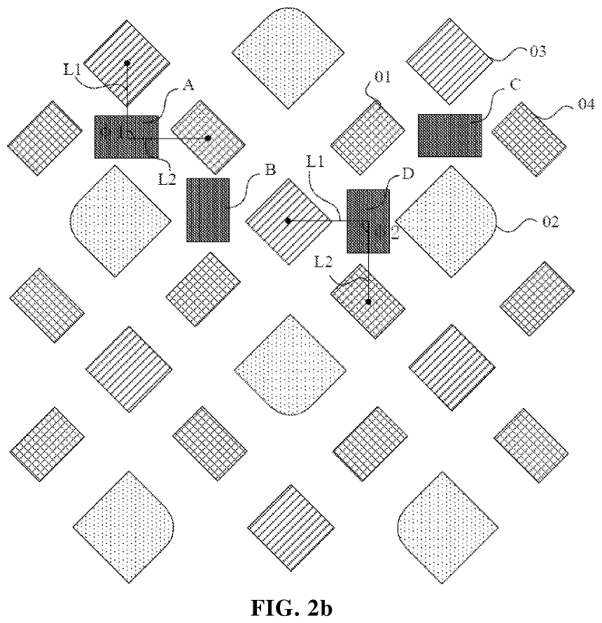

FIG. 3 is a schematic structural diagram showing some support parts in a case where the third subpixel is a blue subpixel and the second subpixel is a red subpixel according to an embodiment of the present disclosure. As shown in FIG. 3, a support part A is disposed between a red subpixel 03 and a blue subpixel 02 adjacent to and disposed in the same column as the red subpixel 03, and a support part B is disposed between the red subpixel 03 and another blue subpixel 02 adjacent to and disposed in the same column as the red subpixel 03.

For at least two of the support parts, a connection line connecting a center of one support part and a center of a third subpixel adjacent to the one support part, and a connection line connecting the center of the one support part and a fourth subpixel adjacent to the one support part form an angle marked as a first angle; a connection line connecting a center of the other support part and a center of a third subpixel adjacent to the other support part, and a connection line connecting the center of the other support part and a fourth subpixel adjacent to the other support part form an angle marked as a second angle; and the first angle and the second angle have different orientations. It should be noted that the center of the subpixel here is, for example, a geometric center of the subpixel, or an intersection point of perpendicular bisectors of respective sides of the subpixel, or a point on the subpixel having substantially the same perpendicular distance to each side. Apparently, the center of the subpixel allows a certain error.

As shown in FIG. 2b, for at least two of the plurality of support parts, a connection line L1 between a center of a support part A and a center of a red subpixel 03 adjacent to the support part A, and a connection line L2 between the center of the one support part A and the green subpixel 04 adjacent to the support part A form an angle marked as a first angle φ1; and a connection line L1 between a center of a support part D and a center of a red subpixel 03 adjacent to the support part D, and a connection line L2 between the center of the one support part D and the green subpixel 04 adjacent to the support part D form an angle marked as a second angle φ2. The first angle φ1 and the second angle φ2 have different orientations. As shown in FIG. 3, for at least two of the plurality of support parts, a connection line L1 between a center of a support part A and a center of a blue subpixel 02 adjacent to the support part A, and a connection line L2 between the center of the one support part A and the green subpixel 04 adjacent to the support part A form an angle marked as a first angle φ1; and a connection line L1 between a center of a support part B and a center of a blue subpixel 02 adjacent to the support part B, and a connection line L2 between the center of the one support part B and the green subpixel 04 adjacent to the support part B form an angle marked as a second angle φ2. The first angle φ1 and the second angle φ2 have different orientations. Here, the different orientations may include different opening orientations of two sides of the angles, two sides of the angles not in parallel, different sizes of the angles, and so on.

As shown in FIGS. 2b and 3, in the embodiment of the present disclosure, the plurality of support parts form a pixel support where the first angle φ1 and the second angle φ2 formed by at least two of the support parts have different orientations, so that the support parts in the entire pixel support are symmetrically arranged, and the FMM supported by the pixel support is relatively flat, thereby improving color cast of the display panel.

In some embodiments, taking the second subpixel being a blue subpixel 02 and the third subpixel being a red subpixel 03 as an example, FIG. 4 is a schematic diagram showing support parts arranged in pairs and support part groups formed of the support parts arranged in a staggered manner according to an embodiment of the present disclosure. As shown in FIG. 4, the plurality of support parts are divided into multiple rows of support part groups, and the support part groups in adjacent rows are staggered in a row direction. The plurality of support parts are divided into multiple columns of support part groups, and the support part groups in adjacent columns are staggered in a column direction. The support part groups include first support part groups 51 and second support part groups 52. The first support part groups 51 and the second support part groups 52 in the same row are alternated in the row direction. Each first support part group 51 includes a first support part 511 and a second support part 512. The first support part 511 is disposed between a blue subpixel 02 and a red subpixel 03 in a pixel unit 100, and the second support part 512 is disposed between a green subpixel 04 in the pixel unit 100 and a green subpixel 01 adjacent to and positioned in a different first pixel row 1 from the green subpixel 04. Each second support part group 52 includes a third support part 513 and a fourth support part 514. The third support part 513 is disposed between a blue subpixel 02 and a red subpixel 03 in a pixel unit 100, and the fourth support part 514 is disposed between a green subpixel 01 in the pixel unit 100 and a green subpixel 04 adjacent to and positioned in a different first pixel row 1 from the green subpixel 01. A first support part group 51 and a second support part group 52 in the same row adjacent to each other are axisymmetric with respect to a straight line passing, in the column direction, through a midpoint of a connection line segment connecting centers of the first support part 511 and the third support part 513. The symmetrical support parts can enable a flat surface the supported FMM, thereby improving color cast of the display panel.

With continued reference to FIG. 4, the plurality of support part groups in the same column are all the first support part groups 51, or all the second support part groups 52; and two adjacent first support part groups 51 in the same column are axisymmetric with respect to a straight line passing, in the row direction, through a midpoint of a connection line segment connecting centers of two first support parts 511. Two adjacent second support part groups 52 in the same column are axisymmetric with respect to a straight line passing, in the row direction, through a midpoint of a connection line segment connecting centers of two third support parts 513. Specifically, for two adjacent first support part groups 51 in the same column, the first support part 511 of one of the first support part groups 51 is disposed between a blue subpixel 02 and a red subpixel 03 in a pixel unit 100, and the second support part 512 is disposed between a green subpixel 04 in the pixel unit 100 and a green subpixel 01 adjacent to and positioned in a next first pixel row 1 of the green subpixel 04. The next first pixel row 1 here refers to a next row relative to a current first pixel row 1 where the green subpixel 04 in the pixel unit 100 is located. The first support part 511 of the other first support part group 51 is disposed between a blue subpixel 02 and a red subpixel 03 in a pixel unit 100, and the second support part 512 is disposed between a green subpixel 04 in the pixel unit 100 and a green subpixel 01 adjacent to and positioned in a previous first pixel row 1 of the green subpixel 04. The previous first pixel row 1 here refers to a previous row relative to a current first pixel row 1 where the green subpixel 04 in the pixel unit 100 is located. For two adjacent second support part groups 52 in the same column, the third support part 513 of one of the second support part groups 52 is disposed between a blue subpixel 02 and a red subpixel 03 in a pixel unit 100, and the fourth support part 514 is disposed between a green subpixel 01 in the pixel unit 100 and a green subpixel 04 adjacent to and positioned in a next first pixel row 1 of the green subpixel 01. The next first pixel row 1 here refers to a next row relative to a current first pixel row 1 where the green subpixel 01 in the pixel unit 100 is located. The third support part 513 of the other second support part group 52 is disposed between a blue subpixel 02 and a red subpixel 03 in a pixel unit 100, and the fourth support part 514 is disposed between a green subpixel 01 in the pixel unit 100 and a green subpixel 04 adjacent to and positioned in a previous first pixel row 1 of the green subpixel 01. The previous first pixel row 1 here refers to a previous row relative to a current first pixel row 1 where the green subpixel 01 in the pixel unit 100 is located. Here, in combination with the above embodiments and as shown in FIG. 4, based on that the first support part group 51 and the second support part group 52 in the same row adjacent to each other are axisymmetric with respect to a straight line passing, in the column direction, through a midpoint of a connection line segment connecting centers of the first support part 511 and the third support part 513, two adjacent first support part groups 51 in the same column are axisymmetric with respect to a straight line passing, in a row direction, through a midpoint of a connection line segment connecting centers of two first support parts 511; and two adjacent second support part groups 52 in the same column are axisymmetric with respect to a straight line passing, in the row direction, through a midpoint of a connection line segment connecting centers of two third support parts 513. Therefore, the symmetry of the support part groups are further enhanced, and color cast of the display panel is improved.

With continued reference to FIG. 4, for a first support part group 51 and a second support part group 52 in the same row adjacent to each other, two green subpixels 04 are between the first support part 511 of the first support part group 51 and the third support part 513 of the second support part group 52, to space apart the first and third support parts 511 and 513. For a first support part group 51 and a second support part group 52 in the same column adjacent to each other, two blue subpixels 02 are between the first support part 511 of the first support part group 51 and the third support part 513 of the second support part group 52, to space apart the first and third support parts 511 and 513.

The staggered support part groups in the embodiment of the present disclosure increases the density of support parts which are uniformly distributed, and improves color cast of the display panel.

In some embodiments, taking the second subpixel being a blue subpixel 02 and the third subpixel being a red subpixel 03 as an example, FIG. 5 is a schematic diagram showing support parts arranged in pairs and support part groups formed of the support parts arranged in an array according to an embodiment of the present disclosure. As shown in FIG. 5, the plurality of support parts are divided into a plurality of support part groups arranged in an array, including first support part groups 51 and second support part groups 52. The first support part groups 51 and the second support part groups 52 in the same row are alternated in the row direction. Each first support part group 51 includes a first support part 511 and a second support part 512. The first support part 511 is disposed between a blue subpixel 02 and a red subpixel 03 in a pixel unit 100, and the second support part 512 is disposed between a green subpixel 04 in the pixel unit 100 and a green subpixel 01 adjacent to and positioned in a different first pixel row 1 from the green subpixel 04. Each second support part group 52 includes a third support part 513 and a fourth support part 514. The third support part 513 is disposed between a blue subpixel 02 and a red subpixel 03 in a pixel unit 100, and the fourth support part 514 is disposed between a green subpixel 01 in the pixel unit 100 and a green subpixel 04 adjacent to and positioned in a different first pixel row 1 from the green subpixel 01. A first support part group 51 and a second support part group 52 in the same row adjacent to each other are axisymmetric with respect to a straight line passing, in the column direction, through a midpoint of a connection line segment connecting centers of the first support part 511 and the third support part 513.

On the basis of the embodiment shown in FIG. 4, some of the support part groups are removed in this embodiment to further enhance symmetry of the support part groups, so that the support parts in the entire pixel support are axisymmetric with respect to a straight line passing, in the column direction, through a center of the pixel support, which enables a flat FMM supported by the support parts, and therefore improves color cast of the display panel.

With continued reference to FIG. 5, the plurality of support part groups arranged in an array, and the plurality of support part groups in the same column are all the first support part groups 51, or all the second support part groups 52. Two adjacent first support part groups 51 in the same column are axisymmetric with respect to a straight line passing, in the row direction, through a midpoint of a connection line segment connecting centers of two first support parts 511. Two adjacent second support part groups 52 in the same column are axisymmetric with respect to a straight line passing, in the row direction, through a midpoint of a connection line segment connecting centers of two third support parts 513. In other words, the support parts in the entire pixel support are axisymmetric with respect to a straight line passing, in the row direction, through a center of the pixel support. Specifically, for two adjacent first support part groups 51 in the same column, the first support part 511 of one of the first support part groups 51 is disposed between a blue subpixel 02 and a red subpixel 03 in a pixel unit 100, and the second support part 512 is disposed between a green subpixel 04 in the pixel unit 100 and a green subpixel 01 adjacent to and positioned in a next first pixel row 1 of the green subpixel 04. The next first pixel row 1 here refers to a next row relative to a current first pixel row 1 where the green subpixel 04 in the pixel unit 100 is located. The first support part 511 of the other first support part group 51 is disposed between a blue subpixel 02 and a red subpixel 03 in a pixel unit 100, and the second support part 512 is disposed between a green subpixel 04 in the pixel unit 100 and a green subpixel 01 adjacent to and positioned in a previous first pixel row 1 of the green subpixel 04. The previous first pixel row 1 here refers to a previous row relative to a current first pixel row 1 where the green subpixel 04 in the pixel unit 100 is located. For two adjacent second support part groups 52 in the same column, the third support part 513 of one of the second support part groups 52 is disposed between a blue subpixel 02 and a red subpixel 03 in a pixel unit 100, and the fourth support part 514 is disposed between a green subpixel 01 in the pixel unit 100 and a green subpixel 04 adjacent to and positioned in a next first pixel row 1 of the green subpixel 01. The next first pixel row 1 here refers to a next row relative to a current first pixel row 1 where the green subpixel 01 in the pixel unit 100 is located. The third support part 513 of the other second support part group 52 is disposed between a blue subpixel 02 and a red subpixel 03 in a pixel unit 100, and the fourth support part 514 is disposed between a green subpixel 01 in the pixel unit 100 and a green subpixel 04 adjacent to and positioned in a previous first pixel row 1 of the green subpixel 01. The previous first pixel row 1 here refers to a previous row relative to a current first pixel row 1 where the green subpixel 01 in the pixel unit 100 is located.

Here, in combination with the above embodiments and as shown in FIG. 5, on the basis that the support parts in the entire pixel support are axisymmetric with respect to a straight line passing, in the column direction, through the center of the pixel support, the support parts in the entire pixel support are set to be axisymmetric with respect to a straight line passing, in the row direction, through a center of the pixel support, thereby further enhancing symmetry of the support part groups and improving color cast of the display panel.

With continued reference to FIG. 5, among the plurality of support part groups arranged in an array (the first support part groups 51 and the second support part groups 52), for a first support part group 51 and a second support part group 52 in the same row adjacent to each other, two green subpixels 04 are between the first support part 511 of the first support part group 51 and the third support part 513 of the second support part group 52, to space apart the first and third support parts 511 and 513. For a first support part group 51 and a second support part group 52 in the same column adjacent to each other, two blue subpixels 02 are between the first support part 511 of the first support part group 51 and the third support part 513 of the second support part group 52, to space apart the first and third support parts 511 and 513.

The support part groups arranged in an array in the embodiment of the present disclosure enhances symmetry of the support part groups, and therefore improves color cast of the display panel. In addition, compared with the embodiment shown in FIG. 4, this embodiment further reduces the density of support part groups, thereby simplifying the manufacturing process of the PS.

In some embodiments, taking the second subpixel being a blue subpixel 02 and the third subpixel being a red subpixel 03 as an example, FIG. 6 is a schematic diagram showing support parts arranged in symmetrical crosses and support part groups formed of the support parts arranged in a staggered manner according to an embodiment of the present disclosure. As shown in FIG. 6, the plurality of support parts are divided into multiple rows of third support part groups 53, and the third support part groups 53 in adjacent rows are staggered in a row direction. The plurality of support parts are divided into multiple columns of third support part groups 53, and the third support part groups 53 in adjacent columns are staggered in a column direction. Each third support part group 53 includes a first support part 511, a second support part 512, a third support part 513, and a fourth support part 514. The first support part 511 is disposed between a blue subpixel 02 and a red subpixel 03 in a pixel unit 100, and the second support part 512, the third support part 514, and the fourth support part 513 are respectively disposed between a green subpixel 04 in the pixel unit 100 and three green subpixels 01 adjacent to the green subpixel 04. Specifically, the first support part 511 of the third support part group 53 is disposed between a blue subpixel 02 and a red subpixel 03 in the pixel unit 100, and the second support part 512 is disposed between the green subpixel 04 in the pixel unit 100 and a green subpixel 01 adjacent to and positioned in a previous first pixel row 1 of the green subpixel 04. The third support part 513 is disposed between the green subpixel 04 in the pixel unit 100 and a green subpixel 01 adjacent to and positioned in a next first pixel row 1 of the green subpixel 04. The previous or next first pixel row 1 here refers to a previous or next row relative to a current first pixel row 1 where the green subpixel 04 in the pixel unit 100 is located. The fourth support part 514 is disposed between the green subpixel 04 in the pixel unit 100 and a green subpixel 01 adjacent to and positioned in the same first pixel row 1 as the green subpixel 04.

On the basis of the embodiments shown in FIGS. 4 and 5, in this embodiment, the support parts in the third support part group 53 are arranged in a symmetrical cross, so that the symmetry of support parts in the support part group, as well as the symmetry of the entire pixel support, is enhanced, flatness of the FMM supported by the support parts is increased, and color cast of the display panel is improved.

With continued reference to FIG. 6, among the plurality of third support part groups 53 arranged in an array, two adjacent third support part groups 53 in the same column are axisymmetric with respect to a straight line passing, in the row direction, through a midpoint of a connection line segment connecting centers of two first support parts 511; and two adjacent third support part groups 53 in the same row are axisymmetric with respect to a straight line passing, in the column direction, through a midpoint of a connection line segment connecting centers of fourth subpixels adjacent to two first support parts 511, respectively. Since the support parts in the third support part group 53 are arranged in a symmetrical cross, the third support part groups 53 in adjacent rows are staggered in the row direction, and the third support part groups 53 in adjacent columns are staggered in the column direction, the PS in the embodiment shown in FIG. 6 has a higher overall symmetry, that is, has a higher symmetry than the embodiments shown in FIGS. 4 and 5, thereby further improving color cast of the display panel.

With continued reference to FIG. 6, for two adjacent third support part groups 53 in the same row, one green subpixel 04 is between the fourth support part 514 in one of the third support part groups 53 and the first support part 511 in the other third support part group 53, to space apart the fourth and first support parts 514 and 511; and for two adjacent third support part groups 53 in the same column, one green subpixel 04 is between the third support part 513 in one of the third support part groups 53 and the second support part 512 in the other third support part group 53, to space apart the third and second support parts 513 and 512.

In some embodiments, taking the second subpixel being a blue subpixel 02 and the third subpixel being a red subpixel 03 as an example, FIG. 7 is a schematic diagram showing support parts arranged in symmetrical crosses and support part groups formed of the support parts arranged in an array according to an embodiment of the present disclosure. As shown in FIG. 7, the plurality of support parts are divided into a plurality of third support part groups 53 arranged in an array. Each third support part group 53 includes a first support part 511, a second support part 512, a third support part 513, and a fourth support part 514. The first support part 511 is disposed between a blue subpixel 02 and a red subpixel 03 in a pixel unit 100, and the second support part 512, the third support part 514, and the fourth support part 513 are respectively disposed between a green subpixel 04 in the pixel unit 100 and three green subpixels 01 adjacent to the green subpixel 04. Specifically, the first support part 511 of the third support part group 53 is disposed between the blue subpixel 02 and the red subpixel 03 in the pixel unit 100, and the second support part 512 is disposed between the green subpixel 04 in the pixel unit 100 and a green subpixel 01 adjacent to and positioned in a previous first pixel row 1 of the green subpixel 04. The third support part 513 is disposed between the green subpixel 04 in the pixel unit 100 and a green subpixel 01 adjacent to and positioned in a next first pixel row 1 of the green subpixel 04. The previous or next first pixel row 1 here refers to a previous or next row relative to a current first pixel row 1 where the green subpixel 04 in the pixel unit 100 is located. The fourth support part 514 is disposed between the green subpixel 04 in the pixel unit 100 and a green subpixel 01 adjacent to and positioned in the same first pixel row 1 of the green subpixel 04.

With continued reference to FIG. 7, among the plurality of third support part groups 53 arranged in an array, two adjacent third support part groups 53 in the same column are axisymmetric with respect to a straight line passing, in a row direction, through a midpoint of a connection line segment connecting centers of two first support parts 511; and two adjacent third support part groups 53 in the same row are axisymmetric with respect to a straight line passing, in the column direction, through a midpoint of a connection line segment connecting centers of green subpixels 04 adjacent to the two first support parts 511, respectively.

On the basis of the embodiment shown in FIG. 6, some of the support part groups are removed in this embodiments that the plurality of third support part groups 53 in the pixel support are arranged in an array, while the support parts in each third support part group 53 are arranged in a symmetrical cross. Therefore, compared with the embodiment shown in FIG. 6, this embodiment further enhances symmetry of the support part groups, so that the support parts are centrosymmetric across the entire pixel support. In addition, in this embodiment, some of the third support part groups 53 are removed compared with the embodiment shown in FIG. 6, which reduces the density of support part groups, thereby simplifying the manufacturing process of the PS.

With continued reference to FIG. 7, among the plurality of third support part groups 53 arranged in an array, for two adjacent third support part groups 53 in the same row, one green subpixel 04 is between the fourth support part 514 in one of the third support part groups 53 and the first support part 511 in the other third support part group 53, to space apart the fourth and first support parts 514 and 511. For two adjacent third support part groups 53 in the same column, one green subpixel 04 is between the third support part 513 in one of the third support part groups 53 and the second support part 512 in the other third support part group 53, to space apart the third and second support parts 513 and 512.

In some embodiments, taking the second subpixel being a blue subpixel 02 and the third subpixel being a red subpixel 03 as an example, FIG. 8 is a schematic diagram showing support parts arranged in symmetrical crosses and support part groups formed of the support parts arranged in a staggered manner according to an embodiment of the present disclosure. As shown in FIG. 8, the support part groups in the embodiment of FIG. 8 are arranged in the same manner as the support part groups in the embodiment of FIG. 6, where the support parts in each support part group are arranged in a symmetrical cross, and FIG. 8 differs from FIG. 6 in that in the embodiment of FIG. 8, for two adjacent third support part groups 53 in the same row, at least three green subpixels 04 are between the fourth support part 514 in one of the third support part groups 53 and the first support part 511 in the other third support part group 53, to space apart the fourth and first support parts 514 and 511; and for two adjacent third support part groups 53 in the same column, at least three green subpixels 04 are between the third support part 513 in one of the third support part groups 53 and the second support part 512 in the other third support part group 53, to space apart the third and second support parts 513 and 512. FIG. 8 merely shows that for two adjacent third support part groups 53 in the same row, three green subpixels 04 are between the fourth support part 514 in one of the third support part groups 53 and the first support part 511 in the other third support part group 53, to space apart the fourth and first support parts 514 and 511; and for two adjacent third support part groups 53 in the same column, three green subpixels 04 are between the third support part 513 in one of the third support part groups 53 and the second support part 512 in the other third support part group 53, to space apart the third and second support parts 513 and 512.

On the basis of the embodiment shown in FIG. 6, a distance between two adjacent third support part groups 53 is doubled in this embodiment, so that a solution with the same PS density as the embodiment shown in FIG. 4 and the embodiment shown in FIG. 7 can be implemented, and the manufacturing process of the PS is simplified.

Each support part in any of the above embodiments may have a contour shape including any one of a rectangular shape, a circular shape, an oval shape, a triangular shape, a drop shape, an asymmetric oval shape, or a trapezoidal shape, and the specific shape may be set according to practical experience, which is not specifically limited in the embodiments of the present disclosure.

In some embodiments, the first subpixel is a green subpixel 01, the fourth subpixel is a green subpixel 04, the second subpixel is a blue subpixel 02, and the third subpixel is a red subpixel 03. An opening corresponding to the blue subpixel 02 has an orthographic projection on a base substrate with a polygonal contour shape; and a corner angle of the opening corresponding to the blue subpixel 02 includes a first corner 61 and a second corner 62 disposed oppositely, and a third corner 63 and a fourth corner 64 disposed oppositely. The second corner 62, the third corner 63, and the fourth corner 64 have the same contour shape, and a distance from an intersection point of extension lines of two sides of the first corner 61 to a center O of the opening is greater than a distance from an intersection point of extension lines of two sides of the second corner 62 to the center O of the opening.

As shown in FIG. 9a, the first corner 61 may be a rounded chamfer, and as shown in FIG. 9b, the first corner 61 may be a flat chamfer. The other corners in the blue subpixel 02 except the first corner 61 are substantially the same. For example, the second corner 62, the third corner 63, and the fourth corner 64 have the same angle, the same contour, the same size, the same fillet curvature, and the like. As shown in FIGS. 9a and 9b, the second corner 62, the third corner 63, and the fourth corner 64 may be close to right angles.

Since the distance from an intersection point of extension lines of two sides of the first corner 61 in the blue subpixel 02 to the center of the opening is greater than a distance from an intersection point of extension lines of two sides of the second corner 62 to the center of the opening, an orthographic projection of the blue subpixel 02 has an irregular contour shape, that is, the blue subpixel 02 corresponds to an irregular opening, and although an upper pixel support is uniformly arranged, it will still cause an uneven stress acting on the pixel defining layer (influenced by the opening in the pixel defining layer itself). To this regard, an embodiment of the present disclosure defines the contour shape of the orthographic projection of the support part. For example, the orthographic projection of the support part on the base substrate has a contour shape including a polygonal shape. Specifically, a corner angle of the support part includes a fifth corner and a sixth corner disposed oppositely, and a seventh corner and an eighth corner disposed oppositely. The sixth corner, the seventh corner, and the eighth corner have the same contour shape, and a distance from an intersection point of extension lines of two sides of the fifth corner of the support part to a center of the support part is greater than a distance from an intersection point of extension lines of two sides of the sixth corner to the center of the support part. The specific contour shape of the orthographic projection of the support part may refer to the contour shape of the orthographic projection of the blue subpixel 02 shown in FIGS. 9a and 9b.

Illustratively, the first corner 61 and the fifth corner have the same contour shape, which may specifically include the same angle, the same fillet curvature and the like, and the fifth corner may be proportionally scaled from the first corner 61.

Illustratively, the contour shape of the orthographic projection of the support part is substantially the same as the contour shape of the orthographic projection of the blue subpixel 02. For example, the first corner 61 is a rounded chamfer, and the fifth corner is also a rounded chamfer; or, the first corner 61 is a flat chamfer, and the fifth corner is also a flat chamfer. Specifically, the two may have the same angle, the same contour, proportionally scaled sizes, the same fillet curvature, and the like.

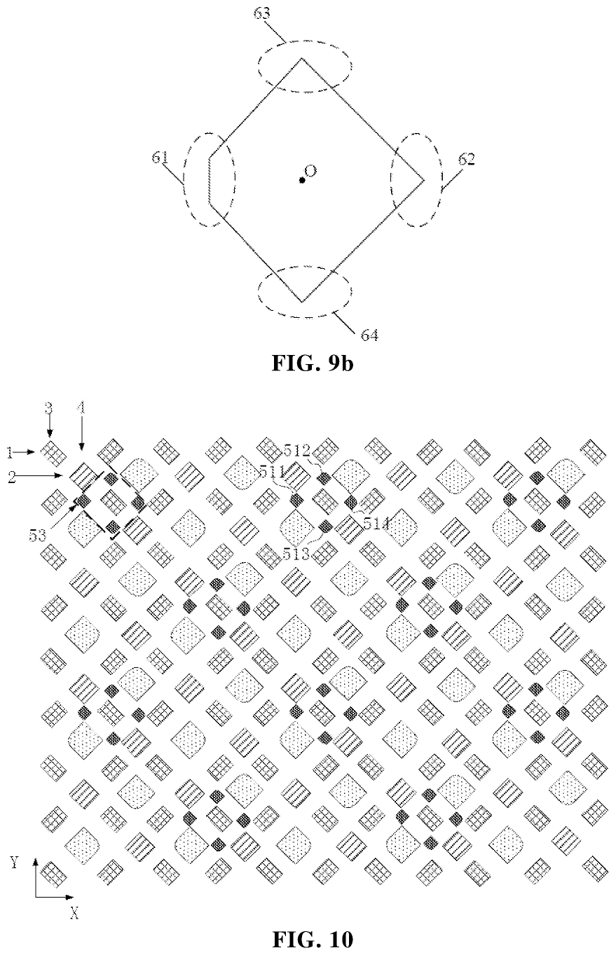

For clarity purposes, in the following embodiments, the first corner 61 of each support part shown in FIGS. 10 to 15 is described as a rounded chamfer as an example, and other contour shapes of the first corner 61 are based on the same principle as that with the rounded chamfer, and are not repeated here.

In some embodiments, taking the second subpixel being a blue subpixel 02 and the third subpixel being a red subpixel 03 as an example, FIG. 10 is a schematic diagram showing support parts arranged in symmetrical crosses and support part groups formed of the support parts arranged in a staggered manner according to an embodiment of the present disclosure. As shown in FIG. 10, the plurality of support parts are divided into multiple rows of third support part groups 53, and the third support part groups 53 in adjacent rows are staggered in a row direction. The plurality of support parts are divided into multiple columns of third support part groups 53, and the third support part groups 53 in adjacent columns are staggered in a column direction. Each third support part group 53 includes a first support part 511, a second support part 512, a third support part 513, and a fourth support part 514. The first support part 511 is disposed between a blue subpixel 02 and a red subpixel 03 in a pixel unit 100, and the second support part 512, the third support part 514, and the fourth support part 513 are respectively disposed between a green subpixel 04 in the pixel unit 100 and three green subpixels 01 adjacent to the green subpixel 04.

In the embodiment shown in FIG. 10, the third support part groups 53 are arranged at positions the same as those in the embodiment of FIG. 6, the specific symmetrical relationship and density may refer to the description of the embodiment of FIG. 6, and repeated descriptions are omitted.

In some embodiments, taking the second subpixel being a blue subpixel 02 and the third subpixel being a red subpixel 03 as an example, FIG. 11 is a schematic diagram showing support parts arranged in symmetrical crosses and support part groups formed of the support parts arranged in an array according to an embodiment of the present disclosure. As shown in FIG. 11, the plurality of support parts are divided into a plurality of third support part groups 53 arranged in an array. Each third support part group 53 includes a first support part 511, a second support part 512, a third support part 513, and a fourth support part 514. The first support part 511 is disposed between a blue subpixel 02 and a red subpixel 03 in a pixel unit 100, and the second support part 512, the third support part 514, and the fourth support part 513 are respectively disposed between a green subpixel 04 in the pixel unit 100 and three green subpixels 01 adjacent to the green subpixel 04.

In the embodiment shown in FIG. 11, the third support part groups 53 are arranged at positions the same as those in the embodiment of FIG. 7, the specific symmetrical relationship and density may refer to the description of the embodiment of FIG. 7, and repeated descriptions are omitted.

In some embodiments, as shown in FIG. 10 or 11, for each support part (including the first support part 511, the second support part 512, the third support part 513, and the fourth support part 514) in the same third support part group 53, the fifth corner is farther away from the green subpixel 04 adjacent to the support part than the sixth corner.

The support part adopted in this embodiment of the present disclosure has a contour shape matched with the contour shape of the blue subpixel, and the fifth corner faces outward, so that the fifth corner has an orientation the same as or perpendicular to the orientation of the first corner 61 of the blue subpixel 02, and is suitable for pixel arrangement of the blue subpixel. Compared with the embodiments shown in FIGS. 6 and 7, this embodiment improves the shape matching between the blue subpixel and the support parts, and therefore enhances consistent distribution of the stress acting on the pixel defining layer by the pixel support.

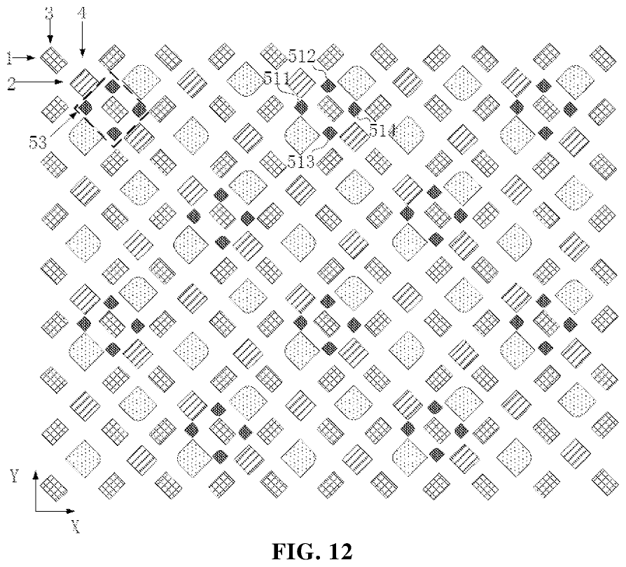

In some embodiments, FIG. 12 is a schematic diagram of support parts in the embodiment of FIG. 11 with fifth corners facing inward. As shown in FIG. 12, for each support part in each third support part group 53, the fifth corner is closer to the green subpixel 04 adjacent to the support part than the sixth corner.

The support part adopted in this embodiment of the present disclosure has a contour shape matched with the contour shape of the blue subpixel, and the fifth corner faces inward, so that the support part has an orientation opposite or perpendicular to the orientation of the first corner 61 of the blue subpixel 02. Compared with the embodiments shown in FIGS. 6 and 7, this embodiment improves the shape symmetry between the blue subpixel and the support parts, and facilitates improvement in the color cast caused by the asymmetry of the support parts around the blue subpixel.

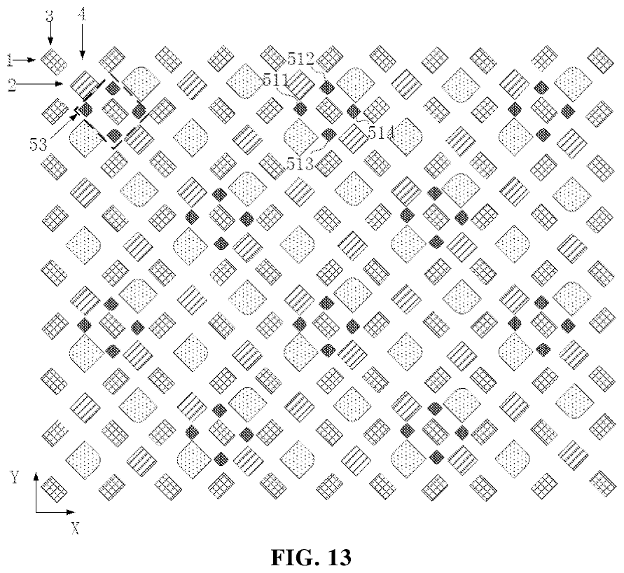

In some embodiments, FIG. 13 is a schematic diagram of support parts in third support part groups of adjacent rows in the embodiment of FIG. 11 with fifth corners having different orientations. As shown in FIG. 13, for two adjacent rows of third support part groups 53, the fifth corner of each support part in one row of third support part groups 53 is closer to a fourth subpixel adjacent to the support part than the sixth corner, while the fifth corner of each support part in the other row of third support part groups 53 is farther away from the green subpixel 04 adjacent to the support part than the sixth corner. In the embodiment of the present disclosure and in combination with the embodiments shown in FIGS. 11 and 12, the fifth corners of some support parts face inward, and the fifth corners of some other support parts face outward. Compared with the arrangement in a single orientation in FIGS. 11 and 12, this embodiment can not only improve the shape matching between the blue subpixel and the support parts, and therefore enhance consistent distribution of the stress acting on the pixel defining layer by the pixel support, but also improve the shape symmetry between the blue subpixel and the support parts, and facilitate improvement in the color cast caused by the asymmetry of the support parts around the blue subpixel.

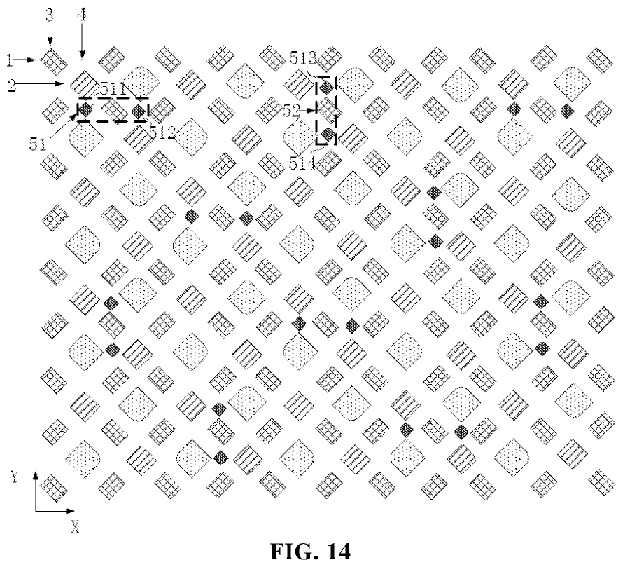

In some embodiments, taking the second subpixel being a blue subpixel 02 and the third subpixel being a red subpixel 03 as an example, FIG. 14 is a schematic diagram showing support parts arranged in pairs and support part groups formed of the support parts arranged in a staggered manner according to an embodiment of the present disclosure. As shown in FIG. 14, the plurality of support parts are divided into multiple rows of support part groups, and the support part groups in adjacent rows are staggered in a row direction. The plurality of support parts are divided into multiple columns of support part groups, and the support part groups in adjacent columns are staggered in a column direction. The support part groups include first support part groups 51 and second support part groups 52. The first support part groups 51 and the second support part groups 52 in the same row are alternated in the row direction. Each first support part group 51 includes a first support part 511 and a second support part 512. The first support part 511 is disposed between a blue subpixel 02 and a red subpixel 03 in a pixel unit 100, and the second support part 512 is disposed between a green subpixel 04 in the pixel unit 100 and a green subpixel 01 adjacent to and positioned in the same first pixel row 1 as the green subpixel 04. Each second support part group 52 includes a third support part 513 and a fourth support part 514. The third support part 513 and the fourth support part 514 are respectively disposed between a green subpixel 01 in the pixel unit 100 and two green subpixels 01 adjacent to and positioned in different first pixel rows 1 from the green subpixel 01.

With continued reference to FIG. 14, for two first support part groups 51 in the same row and closest to each other, the two first support part groups 51 are axisymmetric with regard to a symmetry axis being a straight line passing, in the column direction, through a midpoint of a connection line segment connecting a center of a green subpixel 04 between the first support part 511 and the second support part 512 of one of the first support part groups 51 and a center of a green subpixel 04 between the first support part 511 and the second support part 512 of the other first support part group 51. Similarly, for two second support part groups 52 in the same row and closest to each other, the two second support part groups 52 are axisymmetric with respect to a straight line passing, in the column direction, through a midpoint of a connection line segment connecting centers of the two second support part groups 52. For two first support part groups 51 in the same column and closest to each other, the two first support part groups 51 are axisymmetric with regard to a symmetry axis being a straight line passing, in the row direction, through a midpoint of a connection line segment connecting a center of a green subpixel 04 between the first support part 511 and the second support part 512 of one of the first support part groups 51 and a center of a green subpixel 04 between the first support part 511 and the second support part 512 of the other first support part group 51. Similarly, for two second support part groups 52 in the same column and closest to each other, the two second support part groups 52 are axisymmetric with respect to a straight line passing, in the row direction, through a midpoint of a connection line segment connecting centers of the two second support part groups 52. The symmetrical PS in the embodiment enables a flat FMM supported by the PS, and therefore improves color cast of the display panel.

With continued reference to FIG. 14, for a first support part group 51 and a second support part group 52 in the same row adjacent to each other, one green subpixel 04 is between the green subpixel 04 disposed between the first support part 511 and the second support part 512 in the first support part group 51, and the green subpixel 04 disposed between the first support part 511 and the second support part 512 in the second support part group 52, to space apart the two green subpixels 04. For a first support part group 51 and a second support part group 52 in the same column adjacent to each other, one green subpixel 04 is between the green subpixel 04 disposed between the first support part 511 and the second support part 512 in the first support part group 51, and the green subpixel 04 disposed between the first support part 511 and the second support part 512 in the second support part group 52, to space apart the two green subpixels 04.

The staggered support part groups in the embodiment of the present disclosure increases the density of support parts which are uniformly distributed, and improves color cast of the display panel.

With continued reference to FIG. 14, for two adjacent rows of support part groups, the fifth corner of each support part in one row of support part groups is closer to the green subpixel 04 adjacent to the support part than the sixth corner, while the fifth corner of each support part in the other row of support part groups is farther away from the green subpixel 04 adjacent to the support part than the sixth corner. In other words, based on the embodiment shown in FIG. 13, two support parts are removed from each third support part group 53 to form the first support part group 51 and the second support part group 52 in the embodiment shown in FIG. 14.

This embodiment can not only improve the shape matching between the blue subpixel and the support part and therefore enhance consistent distribution of the stress acting on the pixel defining layer by the pixel support, but also improve the shape symmetry between the blue subpixel and the support parts, and facilitate improvement in the color cast caused by the asymmetry of the support parts around the blue subpixel. Meanwhile, compared with the embodiment shown in FIG. 13, this embodiment reduces the density of support parts, and therefore simplifies the manufacturing process of the PS.

Apparently, for the embodiments shown in FIGS. 13 and 12, the density of support parts can also be reduced by removing some of the third support part groups 53, so that the plurality of support part groups divided from the plurality of support parts are arranged in an array.

In some embodiments, taking the second subpixel being a blue subpixel 02 and the third subpixel being a red subpixel 03 as an example, FIG. 15 is a schematic diagram showing support parts arranged in pairs and in symmetrical crosses, and support part groups formed of the support parts arranged in a staggered manner according to an embodiment of the present disclosure. As shown in FIG. 15, the plurality of support parts are divided into multiple rows of support part groups, and the support part groups in adjacent rows are staggered in a row direction. The plurality of support parts are divided into multiple columns of support part groups, and the support part groups in adjacent columns are staggered in a column direction. The support part groups include first support part groups 51, second support part groups 52, and third support part groups 53. The third support part groups 53 are positioned in even-numbered rows of the plurality of support part groups. The first support part groups 51 and the second support part groups 52 are positioned in odd-numbered rows of the plurality of support part groups, and the first support part groups 51 and the second support part groups 52 in the same row are alternated in the row direction. In this manner, the plurality of support part groups in the same column are all the first support part groups 51, or all the second support part groups 52, or all the third support part groups 53.

Each first support part group 51 includes a first support part 511 and a second support part 512. The first support part 511 is disposed between a blue subpixel 02 and a red subpixel 03 in a pixel unit 100, and the second support part 512 is disposed between a green subpixel 04 in the pixel unit 100 and a green subpixel 01 adjacent to and positioned in a different first pixel row 1 from the green subpixel 04. Illustratively, the second support part 512 may be disposed between the green subpixel 04 in the pixel unit 100 and a green subpixel 01 adjacent to and positioned in a previous first pixel row 1 of the green subpixel 04; or may be disposed between the green subpixel 04 in the pixel unit 100 and a green subpixel 01 adjacent to and positioned in a next first pixel row 1 of the green subpixel 04. To ensure symmetry, for two adjacent first support part groups 51 in the same column, the second support part 512 of one of the first support part groups 51 is disposed between a green subpixel 04 in a pixel unit 100 and a green subpixel 01 adjacent to and positioned in a previous first pixel row 1 of the green subpixel 04, and the second support part 512 of the other first support part group 51 is disposed between a green subpixel 04 in a pixel unit 100 and a green subpixel 01 adjacent to and positioned in a next first pixel row 1 of the green subpixel 04. In this manner, two adjacent first support part groups 51 in the same column are axisymmetric with respect to a straight line passing, in the row direction, through a midpoint of a connection line segment connecting centers of two first support parts 511.

As shown in FIG. 15, each second support part group 52 includes a third support part 513 and a fourth support part 514. The third support part 513 is disposed between a green subpixel 04 in a pixel unit 100 and a green subpixel 01 adjacent to and positioned in the same first pixel row 1 as the green subpixel 04. The fourth support part 514 is disposed between a green subpixel 04 in the pixel unit 100 and a green subpixel 01 adjacent to and positioned in a different first pixel row 1 from the green subpixel 04. Illustratively, to ensure symmetry between the adjacent first support part group 51 and second support part group 52, taking FIG. 15 as an example, the third support part 513 is disposed between a green subpixel 04 in the pixel unit 100 and a right green subpixel 01 adjacent to and positioned in the same first pixel row 1 as the green subpixel 04 (i.e., a green subpixel 01 in a different pixel unit). The fourth support part 514 is disposed between the green subpixel 04 in the pixel unit 100 and a green subpixel 01 adjacent to and positioned in a previous first pixel row 1 of the green subpixel 04. Therefore, a first support part group 51 and a second support part group 52 in the same row adjacent to each other are axisymmetric with respect to a straight line passing, in the column direction, through a midpoint of a connection line segment connecting centers of the first support part 511 and the third support part 513. Further, to ensure symmetry between two adjacent second support part groups 52 in the same column, for two adjacent second support part groups 52 in the same column, the fourth support part 514 of one of the second support part groups 52 is disposed between a green subpixel 04 in a pixel unit 100 and a green subpixel 01 adjacent to and positioned in a previous first pixel row 1 of the green subpixel 04, and the fourth support part 514 of the other second support part group 52 is disposed between a green subpixel 04 in a pixel unit 100 and a green subpixel 01 adjacent to and positioned in a next first pixel row 1 of the green subpixel 04. Therefore, two adjacent second support part groups 52 in the same column are axisymmetric with respect to a straight line passing, in the row direction, through a midpoint of a connection line segment connecting centers of two third support parts 513.

As shown in FIG. 15, each third support part group 53 includes a fifth support part 515, a sixth support part 518, a seventh support part 516, and an eighth support part 517. The fifth support part 515 is disposed between a blue subpixel 02 and a red subpixel 03 in a pixel unit 100, and the sixth support part 516, the seventh support part 518, and the eighth support part 517 are respectively disposed between a green subpixel 04 in the pixel unit 100 and three green subpixels 01 adjacent to the green subpixel 04. To ensure symmetry, two adjacent third support part groups 53 in the same column are axisymmetric with respect to a straight line passing, in the row direction, through a midpoint of a connection line segment connecting centers of two fifth support parts 515; and two adjacent third support part groups 53 in the same row are axisymmetric with respect to a straight line passing, in the column direction, through a midpoint of a connection line segment connecting centers of the fifth support part 515 and the eighth support part 518. Compared with the embodiment shown in FIG. 13, this embodiment reduces the density of support parts, and simplifies the manufacturing process of the PS. Meanwhile, the support part groups symmetrical to each other are beneficial to improving the color cast of the display panel.

With continued reference to FIG. 15, for the first support part group 51 and the second support part group 52, the fifth corner of each support part is closer to the green subpixel 04 adjacent to the support part than the sixth corner; and for the third support part group 53, the fifth corner of each support part is farther away from the green subpixel 04 adjacent to the support part than the sixth corner. In other words, based on the embodiment shown in FIG. 13, two support parts are removed from each third support part group 53 in an odd-numbered row to form the first support part group 51 and the second support part group 52 in the embodiment shown in FIG. 15, while the third support part groups 53 in each even-numbered row remain unchanged.

This embodiment can not only improve the shape matching between the blue subpixel and the support part to some extent, and therefore enhance consistent distribution of the stress acting on the pixel defining layer by the pixel support, but also improve the shape symmetry between the blue subpixel and the support part to some extent, and facilitate improvement in the color cast caused by the asymmetry of the support parts around the blue subpixel. Meanwhile, compared with the embodiment shown in FIG. 13, this embodiment reduces the density of support parts, and therefore simplifies the manufacturing process of the PS.

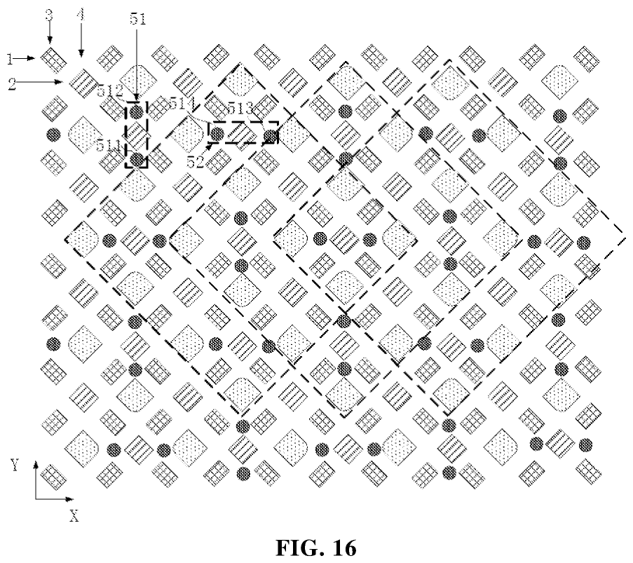

In some embodiments, taking the second subpixel being a red subpixel 03 and the third subpixel being a blue subpixel 02 as an example, FIG. 16 is a schematic diagram showing support parts arranged in pairs and support part groups formed of the support parts arranged in an array according to an embodiment of the present disclosure. As shown in FIG. 16, the plurality of support parts are divided into a plurality of support part groups arranged in an array, including first support part groups 51 and second support part groups 52. The first support part groups 51 and the second support part groups 52 are alternated in both the row direction and the column direction. Each first support part group 51 includes a first support part 511 and a second support part 512. The first support part 511 is disposed between a red subpixel 03 and a blue subpixel 02 in a pixel unit 100, and the second support part 512 is disposed between the red subpixel 03 in the pixel unit 100 and a blue subpixel 02 adjacent to and positioned in a different second subpixel row 2 from the red subpixel 03. Illustratively, the second support part 512 may be disposed between the red subpixel 03 in the pixel unit 100 and a blue subpixel 02 adjacent to and positioned in a previous second subpixel row 2 of the red subpixel 03; or the second support part 512 may be disposed between the red subpixel 03 in the pixel unit 100 and a blue subpixel 02 adjacent to and positioned in a next second subpixel row 2 of the red subpixel 03. To ensure symmetry, for two first support part groups 51 in the same row and closest to each other, the second support part 512 of one of the first support part groups 51 may be disposed between a red subpixel 03 in a pixel unit 100 and a blue subpixel 02 adjacent to and positioned in a previous second subpixel row 2 of the red subpixel 03, and the second support part 512 of the other first support part group 51 is also disposed between a red subpixel 03 in a pixel unit 100 and a blue subpixel 02 adjacent to and positioned in a previous second subpixel row 2 of the red subpixel 03. With such arrangement, two first support part groups 51 in the same row and closest to each other are axisymmetric with respect to a straight line passing, in a column direction, through a midpoint of a connection line segment connecting centers of two first support parts 511. Similarly, to ensure symmetry, for two first support part groups 51 in the same column and closest to each other, the second support part 512 of one of the first support part groups 51 may be disposed between a red subpixel 03 in a pixel unit 100 and a blue subpixel 02 adjacent to and positioned in a previous second subpixel row 2 of the red subpixel 03, and the second support part 512 of the other first support part group 51 is also disposed between a red subpixel 03 in a pixel unit 100 and a blue subpixel 02 adjacent to and positioned in a previous second subpixel row 2 of the red subpixel 03. With such arrangement, two first support part groups 51 in the same column and closest to each other are axisymmetric with respect to a straight line passing, in the row direction, through a midpoint of a connection line segment connecting centers of the first support part 511 and the second support part 512.

Each second support part group 52 includes a third support part 513 and a fourth support part 514. The third support part 513 and the fourth support part 514 are respectively disposed between a red subpixel 03 in a pixel unit 100 and two blue subpixels adjacent to and positioned in the same row as the red subpixel 03. Two second support part groups 52 in the same row and closest to each other are axisymmetric with respect to a straight line passing, in the column direction, through a midpoint of a connection line segment connecting centers of the third support part 513 and the fourth support part 514. Two second support part groups 52 in the same column and closest to each other are axisymmetric with respect to a straight line passing, in the row direction, through a midpoint of a connection line segment connecting centers of two third support parts 513.

In some embodiments, with continued reference to FIG. 16, the first support part 511, the second support part 512, the third support part 513, and the fourth support part 514 each have an orthographic projection with a circular contour shape.

In some embodiments, with continued reference to FIG. 16, for a first support part group 51 and a second support part group 52 in the same row adjacent to each other, one blue subpixel 02 is between the red subpixel 03 disposed between the first support part 511 and the second support part 512 in the first support part group 51, and the red subpixel 03 disposed between the third support part 513 and the fourth support part 514 in the second support part group 52, to space apart the two red subpixels 03. For a first support part group 51 and a second support part group 52 in the same column adjacent to each other, one blue subpixel 02 is between the red subpixel 03 disposed between the first support part 511 and the second support part 512 in the first support part group 51, and the red subpixel 03 disposed between the third support part 513 and the fourth support part 514 in the second support part group 52, to space apart the two red subpixels 03.

It can be seen from FIG. 16 that the PS in the left dashed box includes support parts arranged in “four horizontal pairs and one vertical pair”, the PS in the middle dashed box includes support parts arranged in “one horizontal pair and four vertical pair”, and the PS in the right dashed box includes support parts arranged in “four horizontal pairs and one vertical pair” (i.e., a repetitive unit of the left dashed box). With such arrangement of the PS and the high symmetry of the circular support parts themselves, the overall symmetry of the PS is increased, which is suitable for pixel arrangement of the blue subpixel, and thereby facilitates improvement in the color cast caused by the asymmetry of the support parts around the blue subpixel.

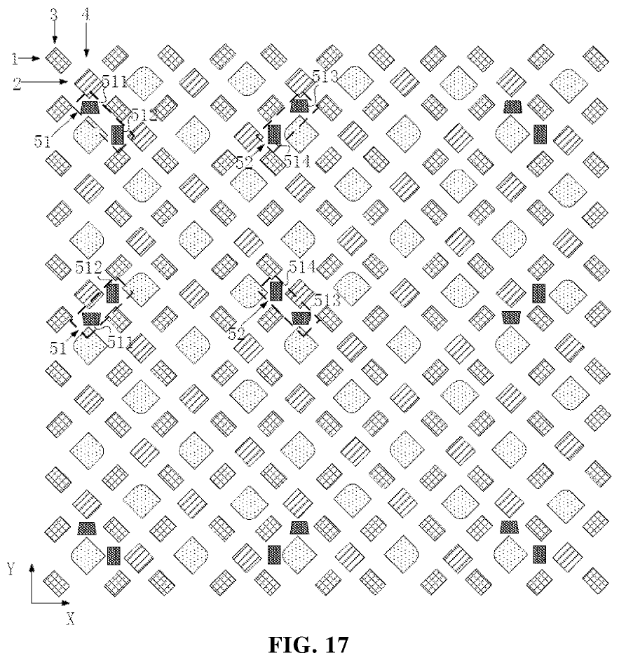

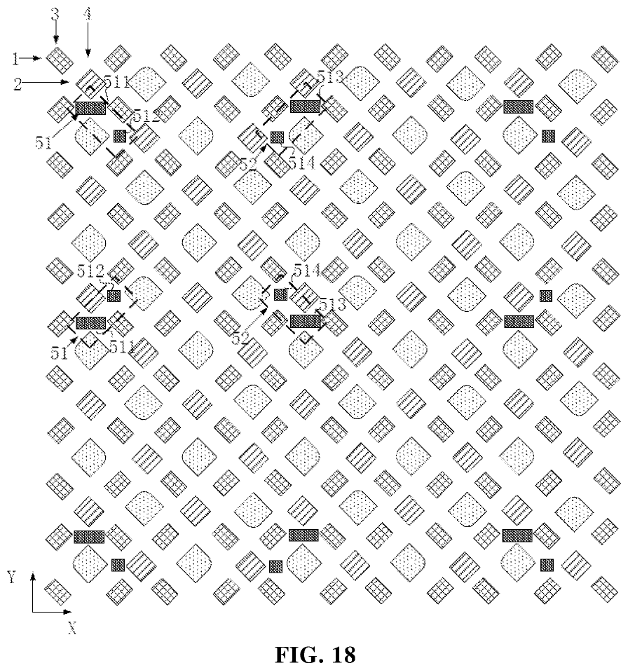

In some embodiments, the PS may have an orthographic projection with a contour shape including at least one of: a rectangular shape, a circular shape, an oval shape, a triangular shape, a drop shape, an asymmetric oval shape, or a trapezoidal shape, for example, any one or combination of the above shapes, such as a combination of a trapezoidal shape and a rectangular shape. FIG. 17 is a schematic diagram showing different shapes of exemplary first support parts and second support parts according to an embodiment of the present disclosure. As shown in FIG. 17, the first support part 511 has a trapezoidal shape, the second support part 512 has a rectangular shape, the third support part 513 has a trapezoidal shape, and the fourth support part 514 has a rectangular shape. Alternatively, the first support part 511 and the second support part 512 in the first support part group 51 are both rectangular, but the first support part 511 is longer in the first direction X than other examples, while the second support part 512 is shorter in the second direction Y than other examples. FIG. 18 is a schematic diagram showing different shapes of exemplary first support parts and second support parts according to another embodiment of the present disclosure. As shown in FIG. 18, as a result, the blocking of colors in left and right direction is reduced, thereby improving color cast of the display panel.

In some embodiments, different colors of subpixels are adjacent to different sizes or different contour shapes of support parts, so as to solve the color cast problem of the corresponding color. For example, by adjusting the sizes and contour shapes of the support parts to address the color cast problem caused by various subpixels, such as by proving the support part having the rounded or flat chamfer adapted to the blue subpixel 02 described above, the purplish blue subpixel 02 (color cast) can be effectively avoided.

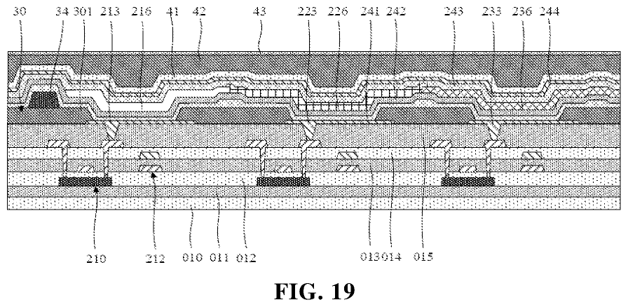

To further clarify the layer structures in the display panel in the embodiments of the present disclosure, an embodiment of the present disclosure further provides a method for manufacturing a display panel, and the layer structures of the display panel in the embodiments of the present disclosure will be described below with reference to the method for manufacturing the display panel. FIG. 19 is a schematic diagram showing layer structures of an exemplary display panel according to an embodiment of the present disclosure. As shown in FIG. 19, the method may specifically include the following steps S11 and S12.

At S11, forming a base substrate 010.

At S12, forming a plurality of pixel units 100 and a plurality of support parts on the base substrate.

Each pixel unit 100 includes a plurality of subpixels, including a first subpixel, a second subpixel, a third subpixel, and a fourth subpixel. The first subpixel, the second subpixel, and the third subpixel are different from each other, and the first subpixel is the same as the fourth subpixel. Among the plurality of pixel units 100, the first subpixel and the fourth subpixel are alternated in a row direction to form a plurality of first pixel rows, and the first subpixel and the fourth subpixel are alternated in a column direction to form a plurality of first pixel columns. The second subpixel and the third subpixel are alternated in the row direction to form a plurality of second pixel rows, and the second subpixel and the third subpixel are alternated in a column direction to form a plurality of second pixel columns. For one second subpixel, a support part is provided between the second subpixel and a third subpixel adjacent to and positioned in the same column as the second subpixel, and a support part is provided between the second subpixel and another third subpixel adjacent to and positioned in the same column as the second subpixel, or a support part is provided between the second subpixel and a third subpixel adjacent to and positioned in the same row as the second subpixel. For at least two of the support parts, a connection line connecting a center of one support part and a center of a third subpixel adjacent to the one support part, and a connection line connecting the center of the one support part and a fourth subpixel adjacent to the one support part form an angle marked as a first angle; a connection line connecting a center of the other support part and a center of a third subpixel adjacent to the other support part, and a connection line connecting the center of the other support part and a fourth subpixel adjacent to the other support part form an angle marked as a second angle; and the first angle and the second angle have different orientations.

The embodiment of the present disclosure provides a method for manufacturing a display panel, which can produce the first angle and the second angle formed by at least two of the support parts having different orientations, so that the support parts are arranged in symmetry, and which enables a relatively flat FMM supported by the support parts, and thereby improving color cast of the display panel.

For step S11, specifically, a base substrate may be manufactured on a glass carrier. In some exemplary implementations, the base substrate 010 may be a flexible base substrate including, for example, a first flexible material layer, a first inorganic material layer, a semiconductor layer, a second flexible material layer, and a second inorganic material layer stacked on the glass carrier. The first and second flexible material layers are made of polyimide (PI), polyethylene terephthalate (PET) or a polymer soft film subjected to surface treatment. The first and second inorganic material layers are made of silicon nitride (SiNx) or silicon oxide (SiOx) or the like, used for improving the water and oxygen resistance of the base substrate, and also referred to as barrier layers. The semiconductor layer is made of amorphous silicon (a-Si). In some exemplary implementations, taking the stacked structure of PI1/Barrier1/a-Si/PI2/Barrier2 as an example, the manufacturing process includes: firstly, coating a layer of polyimide on a glass carrier 1, and curing the layer of polyimide to form a first flexible (PI1) layer; then depositing a barrier film on the first flexible layer to form a first barrier (Barrier1) layer covering the first flexible layer; then depositing an amorphous silicon film on the first barrier layer to form an amorphous silicon (a-Si) layer covering the first barrier layer; then coating another layer of polyimide on the amorphous silicon layer, and curing the another layer of polyimide to form a second flexible (PI2) layer; and then depositing a barrier film on the second flexible layer to form a second barrier (Barrier2) layer covering the second flexible layer, thereby completing manufacturing of the base substrate 010.

The step of forming the plurality of pixel units 100 and the plurality of support parts in step S12 may specifically include steps S12-1 to S12-5.

At S12-1, forming a driving structure layer on the base substrate 010.

The driving structure layer includes a pixel driver circuit for each subpixel, including a plurality of transistors and at least one storage capacitor, for example, a 2T1C, 3T1C, or 7T1C design. The case of three subpixels and the driver circuit for each subpixel including only one transistor and one storage capacitor is taken as an example for illustration.

In some embodiments, the driving structure layer may be manufactured by the following process. The manufacturing process of the driver circuit for a red subpixel 03 will be described below as an example.

A first insulating film and an active layer film are sequentially deposited on the base substrate 010, the first insulating film is patterned through a patterning process to form a first insulation layer 011 covering the entire base substrate 010, and the active layer film is patterned through a patterning process to form an active layer pattern on the first insulation layer 011, the active layer pattern including at least a first active layer.

Then, a second insulating film and a first metal film are sequentially deposited, the second insulating film is patterned through a patterning process to form a second insulation layer 012 covering the active layer pattern, and the first metal film is patterned through a patterning process to form a first gate metal layer pattern on the second insulation layer 012, the first gate metal layer pattern including at least a first gate electrode and a first capacitor electrode.

Then, a third insulating film and a second metal film are sequentially deposited, the third insulating film is patterned through a patterning process to form a third insulation layer 013 covering the first gate metal layer, and the second metal film is patterned through a patterning process to form a second gate metal layer pattern on the third insulation layer 013, the second gate metal layer pattern including at least a second capacitor electrode at a position corresponding to the first capacitor electrode.

Then, a fourth insulating film is deposited, the fourth insulating film is patterned through a patterning process to form a pattern of a fourth insulation layer 014 covering the second gate metal layer, at least two first vias are provided in the fourth insulation layer 014, and parts of the fourth insulation layer 014, the third insulation layer 013 and the second insulation layer 012 in the two first vias are etched off to expose a surface of the first active layer.

Then, a third metal film is deposited, and the third metal film is patterned through a patterning process to form a source-drain metal layer pattern on the fourth insulation layer 014, the source-drain metal layer including at least a first source electrode and a first drain electrode in a display area. The first source electrode and the first drain electrode may be connected to the first active layer through the first vias, respectively.

In the driver circuit for the red subpixel 03 in the display area, the first active layer, the first gate electrode, the first source electrode, and the first drain electrode may form a first transistor 210, and the first capacitor electrode and the second capacitor electrode may form a first storage capacitor 212. In the above manufacturing process, driver circuits for the green subpixel 01, the green subpixel 04, and the blue subpixel 02 may be formed simultaneously.

In some exemplary implementations, the first insulation layer 011, the second insulation layer 012, the third insulation layer 013, and the fourth insulation layer 014 are each made of any one or more of silicon oxide (SiOx), silicon nitride (SiNx), or silicon oxynitride (SiON), and may have a single layer, multiple layers or a composite layer. The first insulation layer 011 is referred to as a buffer layer and configured to improve the water and oxygen resistance of the base substrate; the second insulation layer 012 and the third insulation layer 013 are referred to as gate insulator (GI) layers; and the fourth insulation layer 014 is referred to as an interlayer dielectric (ILD) layer. The first metal film, the second metal film and the third metal film are each made of a metal material including any one or more of silver (Ag), copper (Cu), aluminum (Al), titanium (Ti) or molybdenum (Mo), or an alloy material of the above metals, such as aluminum neodymium (AlNd) or molybdenum niobium (MoNb), and may have a single-layer or multi-layer composite structure, such as Ti/Al/Ti, or the like. The active layer film is made of one or more of amorphous indium gallium zinc oxide (a-IGZO), zinc oxynitride (ZnON), indium zinc tin oxide (IZTO), amorphous silicon (a-Si), polycrystalline silicon (p-Si), hexathiophene, polythiophene or the like. In other words, the present disclosure is applicable to transistors manufactured based on oxide, silicon or organic technologies.

At S12-2, forming a planarization layer 015 on the base substrate with the previously formed pattern.

In some exemplary implementations, a planarization film of an organic material is coated on the base substrate 010 with the previously formed pattern, to form a planarization (PLN) layer 015 covering the entire base substrate 010, and a plurality of second vias are formed in the planarization layer 015 in the display area through mask, exposure and development processes. Parts of the planarization layer 015 in the plurality of second vias is developed to expose a surface of the first drain electrode of the first transistor 210 in the driver circuit for the red subpixel 03, surfaces of first drain electrodes of first transistors in the driver circuits for the green subpixels 01 and 04, and a surface of the first drain electrode of the first transistor in the driver circuit for the blue subpixel 02.

At S12-3, forming a first electrode pattern on the base substrate with the previously formed pattern. In some examples, the first electrode is a reflective anode.

In some exemplary implementations, a conductive film is deposited on the base substrate 010 with the previously formed pattern, and the conductive film is patterned through a patterning process to form a first electrode pattern. A first anode 213 of the red subpixel 03 is connected to the first drain electrode of the first transistor 210 through a second via, a second anode 223 of the green subpixel 01 (or the green subpixel 04) is connected to the first drain electrode of the first transistor of the green subpixel 01 (or the green subpixel 04) through a second via, and a third anode 233 of the blue subpixel 02 is connected to the first drain electrode of the first transistor of the blue subpixel 02 through a second via.

In some examples, the first electrode may be made of a metal material including any one or more of magnesium (Mg), silver (Ag), copper (Cu), aluminum (Al), titanium (Ti) or molybdenum (Mo), or an alloy material of the above metals, such as aluminum neodymium (AlNd) or molybdenum niobium (MoNb), and may have a single-layer or multi-layer composite structure, such as Ti/Al/Ti, or the like, or may be a stack structure of a metal and a transparent conductive material, such as a reflective material of ITO/Ag/ITO, Mo/AlNd/ITO, or the like.

At S12-4, forming a pattern of a pixel defining layer (PDL) 30 on the base substrate with the previously formed pattern.

In some exemplary implementations, a pixel defining film is coated on the base substrate 010 with the previously formed pattern, and masked, developed and exposed to form a pixel defining layer pattern. The pixel defining layer 30 in the display area includes a plurality of subpixel defining parts 301, a plurality of pixel defining layer openings are formed between adjacent subpixel defining parts 301, and parts of the pixel defining layer 30 in the plurality of pixel defining layer openings are developed off to expose at least a partial surface of the first anode 213 of the red subpixel 03, at least a partial surface of the second anode 223 of the green subpixel 01 (or the green subpixel 04), and at least a partial surface of the third anode 233 of the blue subpixel 02, respectively. An orthographic projection of each anode on the base substrate 010 covers an orthographic projection of one of the openings on the base substrate 010.

In some examples, the pixel defining layer 30 may be made of polyimide, acryl, polyethylene terephthalate, or the like.

At S12-5, forming a PS pattern on the base substrate with the previously formed pattern. The PS includes a plurality of support parts 34.

In some exemplary implementations, an organic material film is coated on the base substrate 010 with the previously formed pattern, and masked, developed and exposed to form a PS pattern. The plurality of support parts 34 symmetrically arranged in the PS may be configured to support the FMM in an evaporation process.

Further, an organic functional layer and a second electrode are sequentially formed on the base substrate 010 with the previously formed pattern. In some examples, the second electrode is a transparent cathode. A light-emitting element may emit light from a side away from the base substrate 010 through the transparent cathode, thereby implementing top emission. In some examples, the organic functional layer of the light-emitting element includes: a hole injection layer, a hole transport layer, an emission layer, and an electron transport layer.

In some exemplary implementations, an open mask is adopted to sequentially form through evaporation, on the base substrate 010 with the previously formed pattern, a hole injection layer 241 and a hole transport layer 242, and then an FMM is adopted to sequentially form through evaporation a blue emission layer 236, a green emission layer 216, and a red emission layer 226, each of which is positioned in an opening in the pixel defining layer 30. Then, an open mask is adopted to sequentially form through evaporation an electron transport layer 243 and a cathode 244. The hole injection layer 241, the hole transport layer 242, the electron transport layer 243, and the cathode 244 are all common layers of a plurality of subpixels. In some examples, the organic functional layer may further include: a microcavity adjusting layer between the hole transport layer 242 and the emission layer. For example, after the hole transport layer 242 is formed, an FMM may be adopted to sequentially form through evaporation a blue microcavity adjusting layer, a blue emission layer 236, a green microcavity adjusting layer, a green emission layer 216, a red microcavity adjusting layer, and a red emission layer 226.

In some exemplary implementations, the organic functional layer is formed in a subpixel region to enable connection to the anode. The cathode 224 is formed on the pixel defining layer 30 and connected to the organic functional layer.

In some exemplary implementations, the cathode 224 may be made of any one or more of magnesium (Mg), silver (Ag), aluminum (Al), or an alloy of any one or more of the above metals, or a transparent conductive material, such as indium tin oxide (ITO), or may be a multi-layer composite structure of a metal and a transparent conductive material.

In some exemplary implementations, an optical coupling layer, which may be a common layer of a plurality of subpixels, may be formed on a side of the cathode 244 away from the base substrate 010. The optical coupling layer may cooperate with the transparent cathode to increase light output. For example, the optical coupling layer may be made of a semiconductor material. However, the embodiment is not limited thereto.

After step S12 is performed, an encapsulation layer may be formed on the base substrate with the previously formed pattern.

In some exemplary implementations, an encapsulation layer is formed on the base substrate 010 with the previously formed pattern, where the encapsulation layer may include a first encapsulation layer 41, a second encapsulation layer 42, and a third encapsulation layer 43 in a stack. The first encapsulation layer 41 is made of an inorganic material and covers the cathode 244 in the display area. The second encapsulation layer 42 is made of an organic material. The third encapsulation layer 43 is made of an inorganic material, and covers the first encapsulation layer 41 and the second encapsulation layer 42. However, the embodiment is not limited thereto. In some examples, the encapsulation layer may have a five-layer structure of inorganic/organic/inorganic/organic/inorganic materials.

An embodiment of the present disclosure further provides a display apparatus, including the display panel according to any one of the above embodiments. The display apparatus may be: a mobile phone, a tablet, a television, a monitor, a laptop, a digital album, a navigator or any other product or component having a display function.

It will be appreciated that the above implementations are merely exemplary implementations for the purpose of illustrating the principle of the present disclosure, and the present disclosure is not limited thereto. It will be apparent to those skilled in the art that various modifications and variations may be made without departing from the spirit or essence of the present disclosure. Such modifications and variations should also be considered as falling into the protection scope of the present disclosure.

1. A display panel, comprising a plurality of pixel units each comprising a plurality of subpixels; wherein at least one subpixel in at least one pixel unit is adjacent to at least two support parts, an angle is formed between connection lines respectively connecting centers of the at least two support parts adjacent to the at least one subpixel and a center of the subpixel, and two angles adjacent in a first direction have different orientations.

2. The display panel according to claim 1, wherein the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups comprise first support part groups and second support part groups; and the first support part groups and the second support part groups in the same row are alternated in the row direction;
each first support part group comprises a first support part and a second support part; wherein the first support part is disposed between two of the subpixels, and the second support part is disposed between two of the subpixels; and
each second support part group comprises a third support part and a fourth support part; wherein the third support part is disposed between two of the subpixels, and the fourth support part is disposed between two of the subpixels.

3. The display panel according to claim 2, wherein a first support part group and a second support part group in the same row adjacent to each other are axisymmetric with respect to a straight line passing, in a second direction, through a midpoint of a connection line segment connecting centers of the first support part and the third support part; and/or
two adjacent first support part groups in the same column are axisymmetric with respect to a straight line passing, in the first direction, through a midpoint of a connection line segment connecting centers of two first support parts; the first direction is perpendicular to the second direction; and two adjacent second support part groups in the same column are axisymmetric with respect to a straight line passing, in the first direction, through a midpoint of a connection line segment connecting centers of two third support parts.

4. The display panel according to claim 1, wherein the plurality of support parts are divided into a plurality of support part groups arranged in an array, comprising first support part groups and second support part groups; and the first support part groups and the second support part groups in the same row are alternated in a row direction;
each first support part group comprises a first support part and a second support part; wherein the first support part is disposed between two of the subpixels, and the second support part is disposed between two of the subpixels; and
each second support part group comprises a third support part and a fourth support part; wherein the third support part is disposed between two of the subpixels, and the fourth support part is disposed between two of the subpixels.

5. The display panel according to claim 4, wherein a first support part group and a second support part group in the same row adjacent to each other are axisymmetric with respect to a straight line passing, in a second direction, through a midpoint of a connection line segment connecting centers of the first support part and the third support part; and/or
two adjacent first support part groups in the same column are axisymmetric with respect to a straight line passing, in the first direction, through a midpoint of a connection line segment connecting centers of two first support parts; the first direction is perpendicular to the second direction; and two adjacent second support part groups in the same column are axisymmetric with respect to a straight line passing, in the first direction, through a midpoint of a connection line segment connecting centers of two third support parts.

6. The display panel according to claim 1, wherein the plurality of support parts are divided into multiple rows of third support part groups, and the third support part groups in adjacent rows are staggered in a row direction; and the plurality of support parts are divided into multiple columns of third support part groups, and the third support part groups in adjacent columns are staggered in a column direction; and
each third support part group comprises a first support part, a second support part, a third support part, and a fourth support part arranged around one subpixel of a pixel unit.

7. The display panel according to claim 1, wherein the plurality of support parts are divided into a plurality of third support part groups arranged in an array; and each third support part group comprises a first support part, a second support part, a third support part, and a fourth support part arranged around one subpixel of a pixel unit.

8. The display panel according to claim 7, wherein two adjacent third support part groups in the same column are axisymmetric with respect to a straight line passing, in a row direction, through a midpoint of a connection line segment connecting centers of two first support parts; and
two adjacent third support part groups in the same row are axisymmetric with respect to a straight line passing, in a column direction, through a midpoint of a connection line segment connecting centers of two first support parts.

9. The display panel according to claim 1, wherein the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
groups, and third support part groups; the third support part groups are positioned in even-numbered rows of the plurality of support part groups; and the first support part groups and the second support part groups are positioned in odd-numbered rows of the plurality of support part groups, and the first support part groups and the second support part groups in the same row are alternated in the row direction;
each first support part group comprises a first support part and a second support part; wherein the first support part is disposed between two of the subpixels, and the second support part is disposed between two of the subpixels;
each second support part group comprises a third support part and a fourth support part; wherein the third support part is disposed between two of the subpixels, and the fourth support part is disposed between two of the subpixels; and
each third support part group comprises a fifth support part, a sixth support part, a seventh support part, and an eighth support part arranged around one subpixel of a pixel unit.

10. The display panel according to claim 9, wherein the plurality of support part groups in the same column are all the first support part groups, or all the second support part groups, or all the third support part groups;
two adjacent first support part groups in the same column are axisymmetric with respect to a straight line passing, in the row direction, through a midpoint of a connection line segment connecting centers of two first support parts; two adjacent second support part groups in the same column are axisymmetric with respect to a straight line passing, in the row direction, through a midpoint of a connection line segment connecting centers of two third support parts; and two adjacent third support part groups in the same column are axisymmetric with respect to a straight line passing, in the row direction, through a midpoint of a connection line segment connecting centers of two fifth support parts; and
a first support part group and a second support part group in the same row adjacent to each other are axisymmetric with respect to a straight line passing, in the column direction, through a midpoint of a connection line segment connecting centers of the first support part and the third support part; and two adjacent third support part groups in the same row are axisymmetric with respect to a straight line passing, in the column direction, through a midpoint of a connection line segment connecting centers of the fifth support part and the eighth support part.

11. The display panel according to claim 1, wherein the angle formed between connection lines respectively connecting centers of the at least two support parts adjacent to the at least one subpixel and a center of the subpixel is not equal to 90°.

12. The display panel according to claim 1, wherein the plurality of subpixels comprise a first subpixel, a second subpixel, a third subpixel, and a fourth subpixel, the first subpixel, the second subpixel, and the third subpixel are different from each other, and the first subpixel is the same as the fourth subpixel;
among the plurality of pixel units, the first subpixel and the fourth subpixel are alternated in a row direction to form a plurality of first pixel rows, and the first subpixel and the fourth subpixel are alternated in a column direction to form a plurality of first pixel columns; and the second subpixel and the third subpixel are alternated in the row direction to form a plurality of second pixel rows, and the second subpixel and the third subpixel are alternated in a column direction to form a plurality of second pixel columns;
for one second subpixel, a support part is provided between the second subpixel and a third subpixel adjacent to and positioned in the same column as the second subpixel, and a support part is provided between the second subpixel and another third subpixel adjacent to and positioned in the same column as the second subpixel, or a support part is provided between the second subpixel and a third subpixel adjacent to and positioned in the same row as the second subpixel;
for at least two of the support parts, a connection line connecting a center of one support part and a center of a third subpixel adjacent to the one support part, and a connection line connecting the center of the one support part and a fourth subpixel adjacent to the one support part form an angle marked as a first angle; and a connection line connecting a center of the other support part and a center of a third subpixel adjacent to the other support part, and a connection line connecting the center of the other support part and a fourth subpixel adjacent to the other support part form an angle marked as a second angle; and
the first angle and the second angle have different orientations.

13-21. (canceled)

22. The display panel according to claim 12, wherein the display panel further comprises a base substrate, and a pixel defining layer on the base substrate, the pixel defining layer having openings in one-to-one correspondence with the subpixels;
the first subpixel and the fourth subpixel are both green subpixels, the second subpixel is a blue subpixel, and the third subpixel is a red subpixel; and an opening corresponding to the blue subpixel has an orthographic projection on the base substrate with a polygonal contour shape; and
a corner angle of the opening corresponding to the blue subpixel comprises a first corner and a second corner disposed oppositely, and a third corner and a fourth corner disposed oppositely, the second corner, the third corner, and the fourth corner have the same contour shape, and a distance from an intersection point of extension lines of two sides of the first corner to a center of the opening is greater than a distance from an intersection point of extension lines of two sides of the second corner to the center of the opening.

23. The display panel according to claim 22, wherein the plurality of support parts are divided into multiple rows of third support part groups, and the third support part groups in adjacent rows are staggered in a row direction; and the plurality of support parts are divided into multiple columns of third support part groups, and the third support part groups in adjacent columns are staggered in a column direction; and
each third support part group comprises a first support part, a second support part, a third support part, and a fourth support part; wherein the first support part is disposed between the second subpixel and the third subpixel in the pixel unit, and the second support part, the third support part, and the fourth support part are respectively disposed between the fourth subpixel in the pixel unit and three first subpixels adjacent to the fourth subpixel, or
wherein the plurality of support parts are divided into a plurality of third support part groups arranged in an array; and each third support part group comprises a first support part, a second support part, a third support part, and a fourth support part; wherein the first support part is disposed between the second subpixel and the third subpixel in the pixel unit, and the second support part, the third support part, and the fourth support part are respectively disposed between the fourth subpixel in the pixel unit and three first subpixels adjacent to the fourth subpixel.

24. (canceled)

25. The display panel according to claim 23, wherein an orthographic projection of each support part on the base substrate has a contour shape comprising a polygonal shape; and
a corner angle of the support part comprises a fifth corner and a sixth corner disposed oppositely, and a seventh corner and an eighth corner disposed oppositely, wherein the sixth corner, the seventh corner, and the eighth corner have the same contour shape, and a distance from an intersection point of extension lines of two sides of the fifth corner of the support part to a center of the support part is greater than a distance from an intersection point of extension lines of two sides of the sixth corner to the center of the support part.

26. The display panel according to claim 25, wherein for each support part in each third support part group, the fifth corner is farther away from a fourth subpixel adjacent to the support part than the sixth corner, or
wherein for each support part in each third support part group, the fifth corner is closer to a fourth subpixel adjacent to the support part than the sixth corner, or wherein for two adjacent rows of third support part groups, the fifth corner of each support part in one row of third support part groups is closer to a fourth subpixel adjacent to the support part than the sixth corner, while the fifth corner of each support part in the other row of third support part groups is farther away from a fourth subpixel adjacent to the support part than the sixth corner.

27-31. (canceled)

32. The display panel according to claim 22, wherein the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
the support part groups comprise first support part groups and second support part groups; and the first support part groups and the second support part groups in the same row are alternated in the row direction;
each first support part group comprises a first support part and a second support part; wherein the first support part is disposed between the second subpixel and the third subpixel in the pixel unit, and the second support part is disposed between the fourth subpixel in the pixel unit and a first subpixel adjacent to and positioned in the same first pixel row as the fourth subpixel; and
each second support part group comprises a third support part and a fourth support part; wherein the third support part and the fourth support part are respectively disposed between the fourth subpixel in the pixel unit and two first subpixels adjacent to and positioned in different first pixel rows from the fourth subpixel.

33. (canceled)

34. The display panel according to claim 22, wherein the plurality of support parts are divided into multiple rows of support part groups, and the support part groups in adjacent rows are staggered in a row direction; and the plurality of support parts are divided into multiple columns of support part groups, and the support part groups in adjacent columns are staggered in a column direction;
groups, and third support part groups; the third support part groups are positioned in even-numbered rows of the plurality of support part groups; and the first support part groups and the second support part groups are positioned in odd-numbered rows of the plurality of support part groups, and the first support part groups and the second support part groups in the same row are alternated in the row direction;
each first support part group comprises a first support part and a second support part; wherein the first support part is disposed between the second subpixel and the third subpixel in the pixel unit, and the second support part is disposed between the fourth subpixel in the pixel unit and a first subpixel adjacent to and positioned in a different first pixel row from the fourth subpixel;
each second support part group comprises a third support part and a fourth support part; wherein the third support part is disposed between the fourth subpixel in the pixel unit and a first subpixel adjacent to and positioned in the same first pixel row as the fourth subpixel; the fourth support part is disposed between the fourth subpixel in the pixel unit and a first subpixel adjacent to and positioned in a different first pixel row as the fourth subpixel; and
each third support part group comprises a fifth support part, a sixth support part, a seventh support part, and an eighth support part; wherein the fifth support part is disposed between the second subpixel and the third subpixel in the pixel unit, and the sixth support part, the seventh support part, and the eighth support part are respectively disposed between the fourth subpixel in the pixel unit and three first subpixels adjacent to the fourth subpixel.

35-36. (canceled)

37. The display panel according to claim 12, wherein the plurality of support parts are divided into a plurality of support part groups arranged in an array, comprising first support part groups and second support part groups; and the first support part groups and the second support part groups are alternated in both the row direction and the column direction;
each first support part group comprises a first support part and a second support part; wherein the first support part is disposed between the second subpixel and the third subpixel in the pixel unit, and the second support part is disposed between the second subpixel in the pixel unit and a third subpixel adjacent to and positioned in a different second pixel row from the second subpixel; and
each second support part group comprises a third support part and a fourth support part; wherein the third support part and the fourth support part are respectively disposed between the second subpixel in the pixel unit and two third subpixels adjacent to and positioned in the same row as the second subpixel.

38-41. (canceled)

42. A display apparatus, comprising the display panel according to claim 1.
